(19) United States
(12) Patent Application Publication
(10) Pub. No.: US 2025/0380607 A1
(43) Pub. Date: Dec. 11, 2025

(54) ORGANIC ELECTROLUMINESCENT MATERIALS AND DEVICES

(71) Applicant: Universal Display Corporation, Ewing, NJ (US)

(72) Inventors: Joseph A. MACOR, Philadelphia, PA (US); Rasha HAMZE, Philadelphia, PA (US); Sean Michael RYNO, Yardley, PA (US); Michael HACK, Carmel, CA (US); Julia J. BROWN, Yardley, PA (US)

(73) Assignee: Universal Display Corporation, Ewing, NJ (US)

(21) Appl. No.: 19/199,474

(22) Filed: May 6, 2025

Related U.S. Application Data
(60) Provisional application No. 63/658,273, filed on Jun. 10, 2024.

(51) Int. Cl. H10K 85/10; C08F 128/06; H10K 30/20

(52) U.S. Cl. CPC H10K 85/113; C08F 128/06; H10K 30/211

(57) ABSTRACT

A three-dimensional (3D) organic framework is provided. The 3D organic framework includes a plurality of nodes, A; a plurality of linkers, B; and a plurality of interstitial void spaces, C. The 3D organic framework has a structure wherein each node of the plurality of nodes A is connected to at least another node of the plurality of nodes A through one of the plurality of linkers B; each of the plurality of interstitial void spaces C, can contain one or more molecules E; at least one of A, B, or E is an electron donor; and at least one of A, B, or E is an electron acceptor. An organic photovoltaic (OPV) or an organic photodetector (OPD) device including the 3D organic framework is also provided.

### CROSS-REFERENCES TO RELATED APPLICATIONS

This application claims priority under 35 U.S.C. § 119(e) to U.S. Provisional Application No. 63/658,273, filed on Jun. 10, 2024, the entire contents of which are incorporated herein by reference.

### TECHNICAL FIELD

The present disclosure generally relates to electrically active, optically active, solar, and semiconductor devices, and in particular, to organic photovoltaic cells and organic photodetector devices.

### BACKGROUND

Optoelectronic devices rely on the optical and electronic properties of materials to either produce or detect electromagnetic radiation electronically or to generate electricity from ambient electromagnetic radiation.

Photosensitive optoelectronic devices convert electromagnetic radiation into electricity. Solar cells, also called photovoltaic (PV) devices or cells, are a type of photosensitive optoelectronic device that is specifically used to generate electrical power. PV devices, which may generate electrical energy from light sources other than sunlight, may be used to drive power consuming loads to provide, for example, lighting, heating, or to power electronic circuitry or devices such as calculators, radios, computers or remote monitoring or communications equipment. These power generation applications may involve the charging of batteries or other energy storage devices so that operation may continue when direct illumination from the sun or other light sources is not available, or to balance the power output of the PV device with the specific applications requirements.

Traditionally, photosensitive optoelectronic devices have been constructed of a number of inorganic semiconductors, e.g., crystalline, polycrystalline and amorphous silicon, gallium arsenide, cadmium telluride, and others.

More recent efforts have focused on the use of organic photovoltaic (OPV) cells to achieve acceptable photovoltaic conversion efficiencies with economical production costs. OPVs offer a low-cost, light-weight, and mechanically flexible route to solar energy conversion. Compared with polymers, small molecule OPVs share the advantage of using materials with well-defined molecular structures and weights. This leads to a reliable pathway for purification and the ability to deposit multiple layers using highly controlled thermal deposition without concern for dissolving, and thus damaging, previously deposited layers or sub-cells.

The unique properties of organic semiconductors, such as flexibility and lightness, are increasingly important for information displays, lighting, and energy generation. Unfortunately, OPV cells may suffer from both static and dynamic disorder. This may lead to variable-range carrier hopping, which results in notoriously poor electrical properties with low electron and hole mobilities and correspondingly short charge-diffusion lengths of less than a micrometer.

Additionally, the power conversion efficiency (PCE) for conventional OPV cells has been less than the reported benchmark for market viability of 15%.

As such, there remains a need to develop photoactive frameworks that can be used in OPV cells, devices, and systems.

### SUMMARY

Organic photovoltaic cells (OPVs) and organic photodetectors (OPDs) and their compositions are described herein. In one or more embodiments, the OPV, OPD or solar cell includes: a first electrode (e.g., cathode); a second electrode (e.g., anode); an active layer positioned between the first electrode and the second electrode; and a channel layer positioned between the first electrode and the active layer, wherein the active layer comprises a 3D organic framework, and the channel layer is configured to laterally disperse a charge across the channel layer. In certain examples, the first electrode is arranged in a grid structure having a plurality of electrode segments and a respective opening between adjacent segments of the first electrode.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

### BRIEF DESCRIPTION OF THE DRAWINGS

For a more complete understanding of the disclosure, reference is made to the following detailed description and accompanying drawing figures, in which like reference numerals may be used to identify like elements in the figures.

FIG. 1 is an illustration showing the 3D organic framework having a cube unit cell of Formula I.

FIG. 1A depicts a cross-sectional view of an exemplary OPV device having a channel layer. Due to the presence of the channel layer, the device generates current in response to photons incident on the areas between cathode/anode overlap (e.g., off the grid). This device may be illuminated from the transparent side or grid side, and the dimensions of the grid may vary from hundreds of microns to centimeters in pitch spacing. The increased charge carrier density at the collection area (electrode overlap) may increase the OPV voltage, increasing its power conversion efficiency.

FIGS. 1B-1D depict different examples of a grid arrangement for the electrode (e.g. cathode) of an OPV device, such as represented in FIG. 1A (as viewed in a top-down direction of the OPV device).

FIG. 1E depicts an OPV device without a grid arrangement for an electrode and without a channel layer.

FIG. 2 depicts a variation of an OPV device having a channel layer in which there is broad coverage electrode insulated from the device over the grid electrode. In this example, the charge generation efficiency in regions away from the electrode overlap is modulated by an electric field which may be controlled via the bias voltage between the top electrode and the anode. The electrodes may be transparent or not.

FIG. 3 depicts a variation of an OPV device in which a top electrode is in contact with the collecting grid.

FIG. 4 depicts a variation of an OPV device in which a thick buffer material serves as an insulating layer.

While the disclosed devices and systems are representative of embodiments in various forms, specific embodiments are illustrated in the drawings (and are hereafter described), with the understanding that the disclosure is intended to be illustrative and is not intended to limit the claim scope to the specific embodiments described and illustrated herein.

### DETAILED DESCRIPTION

Various non-limiting examples of OPVs and OPDs and compositions within various layers of an OPV or OPD are described in greater detail below.

### Definitions

As used herein, the term “organic” includes polymeric materials as well as small molecule organic materials that may be used to fabricate organic opto-electronic devices. “Small molecule” refers to any organic material that is not a polymer, and “small molecules” may actually be quite large. Small molecules may include repeat units in some circumstances. For example, using a long chain alkyl group as a substituent does not remove a molecule from the “small molecule” class. Small molecules may also be incorporated into polymers, for example as a pendent group on a polymer backbone or as a part of the backbone. Small molecules may also serve as the core moiety of a dendrimer, which consists of a series of chemical shells built on the core moiety. The core moiety of a dendrimer may be a fluorescent or phosphorescent small molecule emitter. A dendrimer may be a “small molecule,” and it is believed that all dendrimers currently used in the field of OLEDs are small molecules.

As used herein, “top” means furthest away from the substrate, while “bottom” means closest to the substrate. Where a first layer is described as “disposed over” a second layer, the first layer is disposed further away from substrate. There may be other layers between the first and second layer, unless it is specified that the first layer is “in contact with” the second layer. For example, a cathode may be described as “disposed over” an anode, even though there are various organic layers in between.

As used herein, “solution processable” means capable of being dissolved, dispersed, or transported in and/or deposited from a liquid medium, either in solution or suspension form.

A ligand may be referred to as “photoactive” when it is believed that the ligand directly_contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

As used herein, the terms “electrode” and “contact” may refer to a layer that provides a medium for delivering current to an external circuit or providing a bias current or voltage to the device. For example, an electrode, or contact, may provide the interface between the active regions of an organic photosensitive optoelectronic device and a wire, lead, trace or other means for transporting the charge carriers to or from the external circuit. Examples of electrodes include anodes and cathodes, which may be used in a photosensitive optoelectronic device.

As used herein, the term “transparent” may refer to a material that permits at least 50% of the incident electromagnetic radiation in relevant wavelengths to be transmitted through it. In a photosensitive optoelectronic device, it may be desirable to allow the maximum amount of ambient electromagnetic radiation from the device exterior to be admitted to the photoconductive active interior region. That is, the electromagnetic radiation must reach a photoconductive layer(s), where it can be converted to electricity by photoconductive absorption. This often dictates that at least one of the electrical contacts or electrodes should be minimally absorbing and minimally reflecting of the incident electromagnetic radiation. In some cases, such a contact should be transparent or at least semi-transparent. In one embodiment, the transparent material may form at least part of an electrical contact or electrode.

As used herein, the term “semi-transparent” may refer to a material that permits some, but less than 50% transmission of ambient electromagnetic radiation in relevant wavelengths. Where a transparent or semi-transparent electrode is used, the opposing electrode may be a reflective material so that light which has passed through the cell without being absorbed is reflected back through the cell.

As used and depicted herein, a “layer” refers to a member or component of a device, for example an optoelectronic device, being principally defined by a thickness, for example in relation to other neighboring layers, and extending outward in length and width. It should be understood that the term “layer” is not necessarily limited to single layers or sheets of materials. In addition, it should be understood that the surfaces of certain layers, including the interface(s) of such layers with other material(s) or layers(s), may be imperfect, wherein said surfaces represent an interpenetrating, entangled or convoluted network with other material(s) or layer(s). Similarly, it should also be understood that a layer may be discontinuous, such that the continuity of said layer along the length and width may be disturbed or otherwise interrupted by other layer(s) or material(s).

As used herein, a “photoactive region” refers to a region of a device that absorbs electromagnetic radiation to generate excitons. Similarly, a layer is “photoactive” if it absorbs electromagnetic radiation to generate excitons. The excitons may dissociate into an electron and a hole in order to generate an electrical current.

As used herein, the terms “donor” and “acceptor” refer to the relative positions of the highest occupied molecular orbital (“HOMO”) and lowest unoccupied molecular orbital (“LUMO”) energy levels of two contacting but different organic materials. If the LUMO energy level of one material in contact with another is lower, then that material is an acceptor. Otherwise it is a donor. It is energetically favorable, in the absence of an external bias, for electrons at a donor-acceptor junction to move into the acceptor material, and for holes to move into the donor material.

As used herein, a first “Highest Occupied Molecular Orbital” (HOMO) or “Lowest Unoccupied Molecular Orbital” (LUMO) energy level is “greater than” or “higher than” a second HOMO or LUMO energy level if the first energy level is closer to the vacuum energy level. Because ionization potentials (IP) are measured as a negative energy relative to a vacuum level, a higher HOMO energy level corresponds to an IP having a smaller absolute value (an IP that is less negative). Similarly, a higher LUMO energy level corresponds to an electron affinity (EA) having a smaller absolute value (an EA that is less negative). On a conventional energy level diagram, with the vacuum level at the top, the LUMO energy level of a material is higher than the HOMO energy level of the same material. A “higher” HOMO or LUMO energy level appears closer to the top of such a diagram than a “lower” HOMO or LUMO energy level.

As used herein, the term “band gap” (E_{g}) of a polymer may refer to the energy difference between the HOMO and the LUMO. The band gap is typically reported in electron volts (eV). The band gap may be measured from the UV-vis spectroscopy or cyclic voltammetry. A “low band gap” polymer may refer to a polymer with a band gap below 2 eV, e.g., the polymer absorbs light with wavelengths longer than 620 nm.

As used herein, the term “excitation binding energy” (E_{B}) may refer to the following formula: E_{B}=(M⁺+M⁻)−(M*+M), where M⁺ and M⁻ are the total energy of a positively and negatively charged molecule, respectively; M* and M are the molecular energy at the first singlet state (S₁) and ground state, respectively. Excitation binding energy of acceptor or donor molecules affects the energy offset needed for efficient exciton dissociation. In certain examples, the escape yield of a hole increases as the HOMO offset increases. A decrease of exciton binding energy E_{B} for the acceptor molecule leads to an increase of hole escape yield for the same HOMO offset between donor and acceptor molecules.

As used herein, “power conversion efficiency” (PCE) (ηₚ) may be expressed as:

$${η}_{ρ} = \frac{{V}_{OC} * FF * {J}_{SC}}{{P}_{O}}$$

wherein V_{OC} is the open circuit voltage, FF is the fill factor, J_{SC} is the short circuit current, and P_{O} is the input optical power.

As used herein, “spin coating” may refer to the process of solution depositing a layer or film of one material (i.e., the coating material) on a surface of an adjacent substrate or layer of material. The spin coating process may include applying a small amount of the coating material on the center of the substrate, which is either spinning at low speed or not spinning at all. The substrate is then rotated at high speed in order to spread the coating material by centrifugal force. Rotation is continued while the fluid spins off the edges of the substrate, until the desired thickness of the film is achieved. The applied solvent is usually volatile, and simultaneously evaporates. Therefore, the higher the angular speed of spinning, the thinner the film. The thickness of the film also depends on the viscosity and concentration of the solution and the solvent.

As used herein, and as would be generally understood by one skilled in the art, a first work function is “greater than” or “higher than” a second work function if the first work function has a higher absolute value. Because work functions are generally measured as negative numbers relative to vacuum level, this means that a “higher” work function is more negative. On a conventional energy level diagram, with the vacuum level at the top, a “higher” work function is illustrated as further away from the vacuum level in the downward direction. Thus, the definitions of HOMO and LUMO energy levels follow a different convention than work functions.

Details on OLEDs, and the definitions described above, can be found in U.S. Pat. No. 7,279,704, which is incorporated herein by reference in its entirety.

### Organic Photovoltaic Cells

As disclosed herein, the various compositions or molecules may be provided within a solar cell or organic photovoltaic (OPV) cell. As supported by the Example section below, the various compositions or molecules for an OPV cell disclosed herein may be advantageous in providing one or more improvements over conventionally known OPV cells. Specifically, the various OPV cell layers and devices may provide an improved power conversion efficiency over conventionally known OPV cells and devices.

An organic photodetector (OPD) is similar to an OPV device except that it is usually designed to operate under reverse electrical bias such that it produces a photocurrent in response to incident absorbed photons. As such it is used to detect light or other electromagnetic radiation as opposed to an OPV which converts the incident radiation into electrical power.

As disclosed herein, the improved OPV cells and devices may include a channel layer configured to improve lateral dispersion of a charge across the layer and improve overall power generation or power efficiency of the OPV cell/device. Additionally, or alternatively, the improved OPV cells and devices may include a sparse metal grid or thin metal finger electrode (e.g., cathode) that may improve the transparency of the OPV cell. These embodiments, along with additional embodiments of the improved OPV cell compositions are discussed in greater detail below.

Although devices may be described herein for use in OPV cells, it is understood that devices, layer configurations, and methods of the present disclosure may also be used in a variety of other optoelectronic devices, including but not limited to OPDs, charge coupled devices (CCDs), photosensors, or any other suitable device.

### Organic Photovoltaic Cell Overview

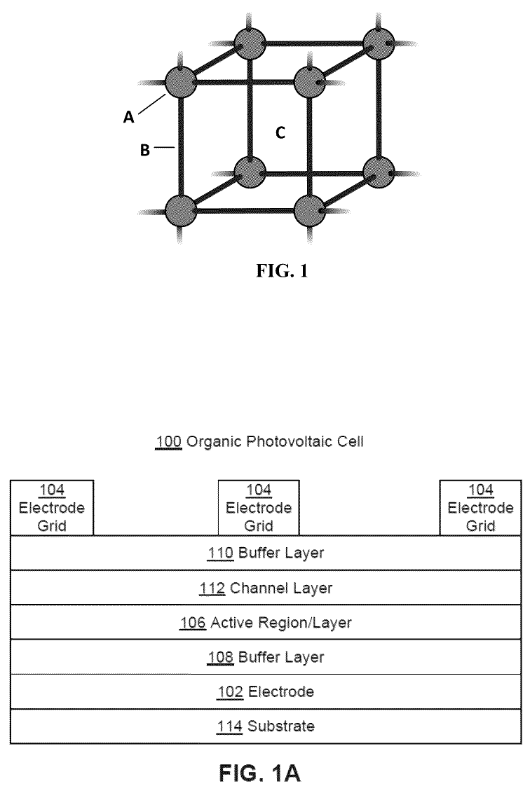

FIG. 1A depicts a cross-sectional view of an exemplary organic photovoltaic (OPV) device having a channel layer. Due to the presence of the channel layer, the device generates current in response to photons incident on the areas between cathode/anode overlap (e.g., off the grid). This device may be illuminated from the transparent side or grid side, and the dimensions of the grid may vary from hundreds of microns to centimeters in pitch spacing. The increased charge carrier density at the collection area (electrode overlap) may increase the OPV voltage, increasing its power conversion efficiency.

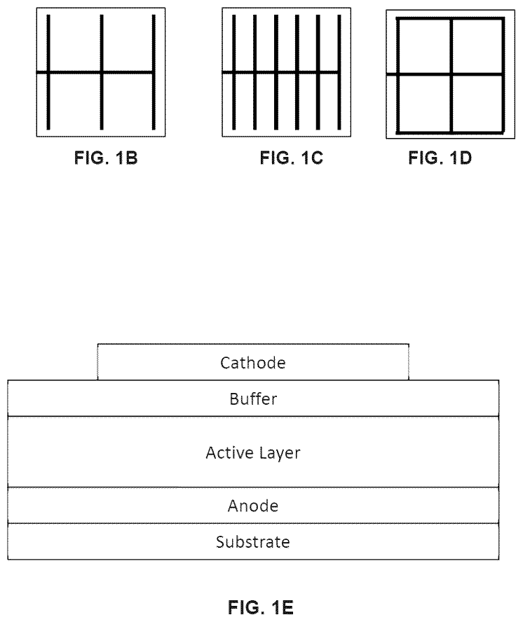

FIG. 2 depicts a variation of an OPV device having a channel layer in which there is broad coverage electrode insulated from the device over the grid electrode. In this example, the charge generation efficiency in regions away from the electrode overlap is modulated by an electric field which may be controlled via the bias voltage between the top electrode and the anode. The electrodes may be transparent or not.

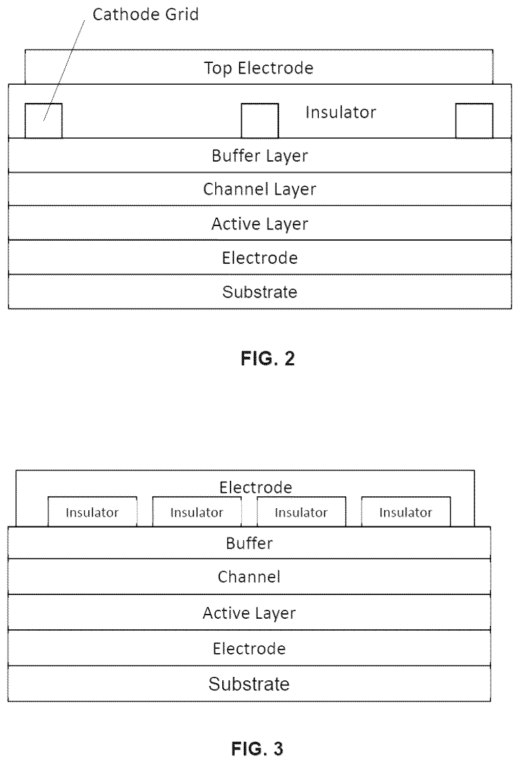

FIG. 3 depicts a variation of an OPV device in which a top electrode is in contact with the collecting grid.

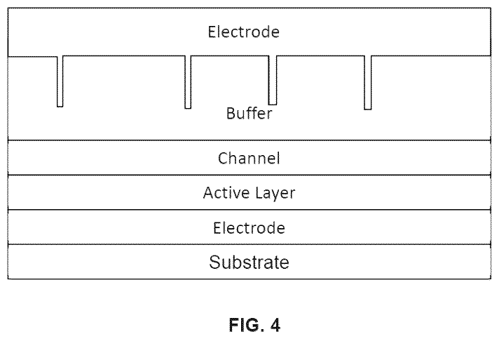

FIG. 4 depicts a variation of an OPV device in which a thick buffer material serves as an insulating layer.

The various layers depicted in these figures will be described in greater detail with reference to FIG. 1A. In FIG. 1A, the OPV device 100 may include an OPV cell having two electrodes 102, 104 (e.g., an anode and a cathode) in superposed relation, at least one donor composition, and at least one acceptor composition, wherein the donor-acceptor material (e.g., heterojunction) or active layer 106 is positioned between the two electrodes 102, 104. At least one buffer layer 108 may be positioned between the first electrode 102 and the active layer 106. Additionally, or alternatively, at least one buffer layer 108, 110 may be positioned between the active layer 106 and the electrode 102, 104. Further, a channel layer 112 may be positioned between the active layer 106 and one of the electrodes (e.g., the second electrode 104).

As depicted in FIG. 1A, an electrode or outer layer (e.g., the first electrode 102) of the OPV cell may be positioned on a substrate 114 (e.g., glass).

Non-limiting examples of the various compositions of the various layers of the OPVs are described herein.

### First Electrode (e.g., Anode)

In certain examples, the first electrode 102 positioned adjacent to a substrate may be the anode 102. While the examples further disclosed within this disclosure refer to the first electrode 102 as the anode (the alternative may apply, wherein the first electrode is the cathode).

The anode 102 may include a conducting oxide, thin metal layer, or conducting polymer. In some examples, the anode 102 includes a (e.g., transparent) conductive metal oxide such as indium tin oxide (ITO), tin oxide (TO), gallium indium tin oxide (GITO), zinc oxide (ZO), or zinc indium tin oxide (ZITO). In other examples, the anode 102 includes a thin metal layer, wherein the metal is selected from the group consisting of Ag, Au, Pd, Pt, Ti, V, Zn, Sn, Al, Co, Ni, Cu, Cr, or combinations thereof. In yet other examples, the anode 102 includes a (e.g., transparent) conductive polymer such as polyanaline (PANI), or 3,4-polyethyl-enedioxythiophene:polystyrenesulfonate (PEDOT:PSS).

The thickness of the anode 102 may be 0.1-1000 nm, 1-10 nm, 0.1-10 nm, 10-100 nm, or 100-1000 nm.

In some examples, an anti-reflective coating (ARC) may be positioned on an exterior surface of the anode 102. This may be advantageous in further improving the power conversion efficiency (PCE) of the solar cell. In some examples, the PCE may be improved by 1-10% or about 5% with the addition of the ARC.

The ARC may include a plurality of layers with alternating layers of contrasting refractive index. The plurality of layers of the ARC may include a first layer having magnesium fluoride and a second layer having silicon oxide. In some examples, the ARC has a thickness in a range of 1-1000 nm, 10-500 nm, 100-500 nm, or 100-200 nm.

### Second Electrode (e.g., Cathode Grid)

The second electrode or cathode 104 may be a conducting oxide, thin metal layer, or conducting polymer similar or different from the materials discussed above for the anode 102. In certain examples, the cathode 104 may include a metal or metal alloy. The cathode 104 may include Ca, Al, Mg, Ti, W, Ag, Au, or another appropriate metal, or an alloy thereof.

The thickness of the cathode 104 may be 0.1-1000 nm, 1-10 nm, 0.1-10 nm, 10-100 nm, or 100-1000 nm.

In some examples, an anti-reflective coating (such as described above for the anode) may be positioned on an exterior surface of the cathode 104.

In certain examples, the second electrode or cathode 104 is arranged in a grid structure having a plurality of electrode segments (e.g., metal fingers) and a respective opening between adjacent segments of the electrode. This sparse (e.g., metal) grid arrangement or thin metal finger arrangement may be advantageous in improving the overall transparency of the OPV cell, based on the openings between the segments. In certain examples, the segments of the electrode make up less than 50%, less than 25%, less than 20%, less than 10%, less than 5%, or less than 1% of the overall surface area of the electrode (as viewed in a direction perpendicular to the electrode layer), while the remaining surface area is a transparent opening (e.g., without any composition or material in the electrode layer).

FIGS. 1B-1D depict different examples of a grid arrangement for the electrode (e.g. cathode) of the OPV device, such as represented in FIG. 1A (as viewed in a top-down direction of the OPV device). In FIG. 1B, three electrode segments or thin metal fingers are positioned along a first axis, separated from one another. The distance between each segment may be variable. FIG. 1B also depicts one electrode segment positioned along a second axis, perpendicular to the first axis.

FIGS. 1C and 1D represent further examples having a different arrangement of electrode segments positioned along the first and second axes. Further configurations are also possible (such as, e.g., an electrode segment not positioned along either of the axes).

In combination with the channel layer, discussed in greater detail below, the sparse electrode layer may advantageously provide a higher operating voltage than a conventional organic photovoltaic cell (such as depicted in FIG. 1E) that has two conventional electrode arrangements and no channel layer. The higher operating voltage of the OPV device, such as depicted in FIGS. 1A-1D may be due to the concentration of a large current to the sparse electrodes. Such an effect can be derived from the Shockley ideal diode equation:

$$I = {I}_{D} [ exp ( \frac{{V}_{D}}{{k}_{B} T} ) - 1 ] - {I}_{photo} \qquad ( 1 )$$

In Equation (1), I is the overall current flowing in the device, I_{D} is the diode reverse bias saturation current, V_{D} is the voltage applied to the diode, k_{B} is Boltzmann's constant, T is temperature, and Iₚₕₒₜₒ is the photocurrent generated by the device under illumination. Under open-circuit conditions, where I=0 this equation yields:

$$0 = {I}_{D} [ exp ( \frac{{V}_{OC}}{{k}_{B} T} ) - 1 ] - {J}_{photo} \qquad ( 2 )$$

In Equation (2), V_{OC} is the open-circuit voltage. Rearranging, it can be shown that:

$${V}_{OC} = {k}_{B} \cdot T \cdot ln ( \frac{{I}_{photo}}{{I}_{D}} ) + 1 \qquad ( 3 )$$

Thus, the structures shown in FIGS. 1A-1D, 2, 3, and 4 have an increased current density collected locally at the contacts, an increased open-circuit voltage is expected.

Importantly, the device may be highly transparent and also highly efficient because the collecting area does not necessarily have a metal contact covering its entire surface as do most conventional OPVs (such as depicted in FIG. 1E).

### Buffer Layers

As noted above, the OPV may include one or more charge collecting/transporting buffer or electron blocking layers 108, 110 positioned between an electrode 102, 104 and the active region or layer 106. The buffer layer(s) is/are advantageous in protecting the adjacently positioned layers or compositions from adversely interacting with each other. Additionally, certain compositions within the buffer layer may be advantageous in further improving the power conversion efficiency (PCE) of the OPV or solar cell.

The first and second buffer layers 108, 110 may individually be a metal oxide layer. In certain examples, the first and second buffer layers 108, 110 may individually include one or more of MoO₃, V₂O₅, ZnO, or TiO₂. In some examples, the first buffer layer 108 has a similar composition as the second buffer layer 110. In other examples, the first and second buffer layers 108, 110 have different compositions.

The first and/or second buffer layers 108, 110 may include vacuum-deposited electron transporting compositions or molecules.

In some examples, the first and/or second buffer layers 108, 110 are selected from the group consisting of:

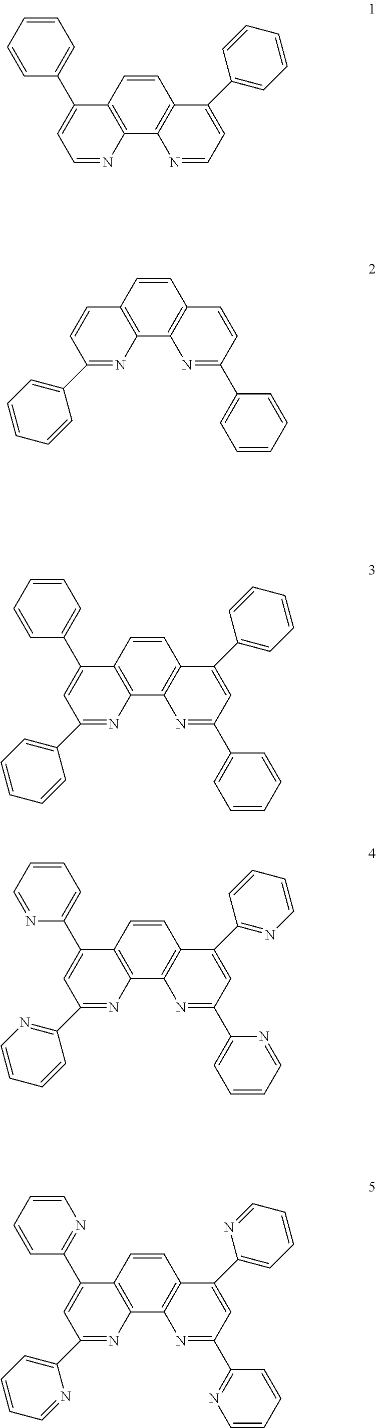 [SMILES: c1ccc(-c2ccnc3c2ccc2c(-c4ccccc4)ccnc23)cc1 ; c1ccc(-c2ccc3ccc4ccc(-c5ccccc5)nc4c3n2)cc1 ; c1ccc(-c2cc(-c3ccccc3)c3ccc4c(-c5ccccc5)cc(-c5ccccc5)nc4c3n2)cc1 ; c1ccc(-c2cc(-c3ccccn3)c3ccc4c(-c5ccccn5)cc(-c5ccccn5)nc4c3n2)nc1 ; c1ccc(-c2cc(-c3ccccn3)c3ccc4c(-c5ccccn5)cc(-c5ccccn5)nc4c3n2)nc1]

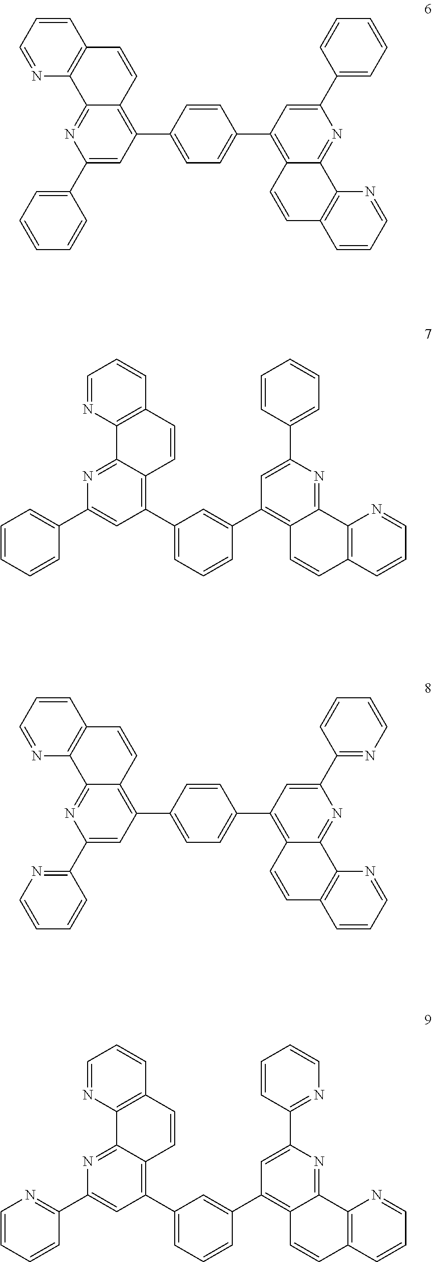 [SMILES: c1ccc(-c2cc(-c3ccc(-c4cc(-c5ccccc5)nc5c4ccc4cccnc45)cc3)c3ccc4cccnc4c3n2)cc1 ; c1ccc(-c2cc(-c3cccc(-c4cc(-c5ccccc5)nc5c4ccc4cccnc45)c3)c3ccc4cccnc4c3n2)cc1 ; c1ccc(-c2cc(-c3ccc(-c4cc(-c5ccccn5)nc5c4ccc4cccnc45)cc3)c3ccc4cccnc4c3n2)nc1 ; c1ccc(-c2cc(-c3cccc(-c4cc(-c5ccccn5)nc5c4ccc4cccnc45)c3)c3ccc4cccnc4c3n2)nc1]

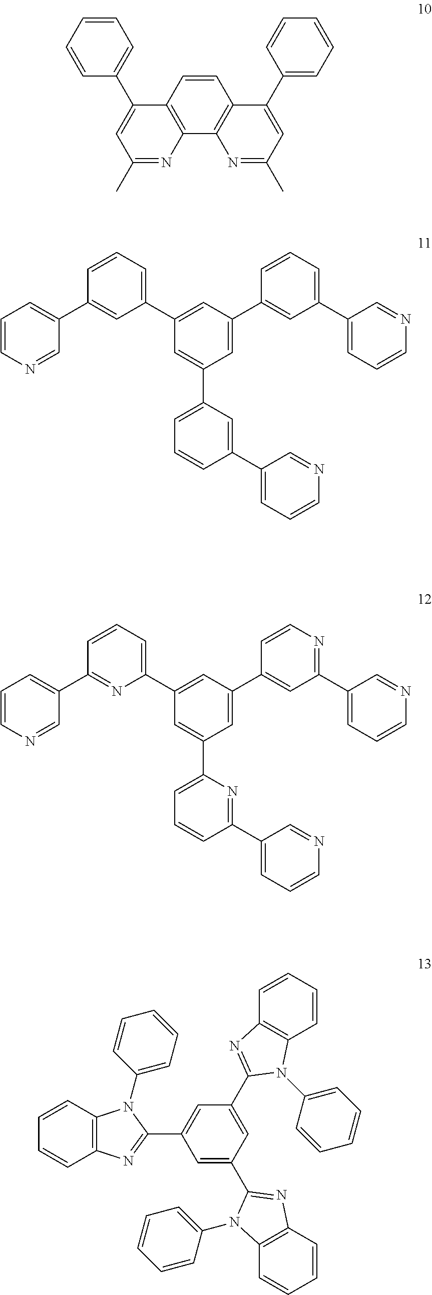 [SMILES: Cc1cc(-c2ccccc2)c2ccc3c(-c4ccccc4)cc(C)nc3c2n1 ; c1cncc(-c2cccc(-c3cc(-c4cccc(-c5cccnc5)c4)cc(-c4cccc(-c5cccnc5)c4)c3)c2)c1 ; c1cncc(-c2cc(-c3cc(-c4cccc(-c5cccnc5)n4)cc(-c4cccc(-c5cccnc5)n4)c3)ccn2)c1 ; c1ccc(-n2c(-c3cc(-c4nc5ccccc5n4-c4ccccc4)cc(-c4nc5ccccc5n4-c4ccccc4)c3)nc3ccccc32)cc1]

In certain examples, the first and/or second buffer layers 108, 110 include one or more of the following: 3,3′,5,5′-Tetra[(m-pyridyl)-phen-3-yl]biphenyl; 1,3-Bis[3,5-di(pyridin-3-yl)phenyl]benzene; 1,3,5-Tri(p-pyrid-3-yl-phenyl)benzene; or 2,4,6-Tris(3′-(pyridin-3-yl)biphenyl-3-yl)-1,3,5-triazine.

In one particular example, the first and/or second buffer layer 108, 110 includes 4,7-Diphenyl-1,10-phenanthroline (i.e., bathophenanthroline or “Bhen”) or a mixture of BPhen and a fullerene composition (e.g., C₆₀). In some examples, the mixed electron blockers or buffer layer may include a 1:1 volume ratio BPhen:C₆₀ (e.g., with BPhen adjacent to the electrode).

The thickness of each buffer layer 108, 110 may be 0.1-100 nm, 0.1-50 nm, 1-10 nm, 0.1-10 nm, or 10-100 nm.

### Active Layer

As noted above, at least one active layer 106 or organic heterojunction layer is present between the two electrodes 102, 104. The thickness of the active layer is variable. In certain examples, the thickness of the active layer 106 may be less than 100 nm, or in a range of 10-100 nm, 50-100 nm, or 60-90 nm.

The active region or layer 106 positioned between the electrodes includes a composition or molecule having an acceptor and a donor. The composition may be arranged as an acceptor-donor-acceptor (A-D-A) or donor-acceptor-acceptor (d-a-a′). The compositions of the active layer or organic heterojunction may be selected to allow for lateral disperse a charge across the layer. In one embodiment, the active layer comprises an acceptor and a highly dipolar donor which destabilizes the HOMO energy of the acceptor, thereby providing energetic confinement of electrons in the channel layer.

Various examples of donor and acceptor compositions for each individual active layer are discussed in greater detail below.

### Donor Composition of Active Layer

In certain examples, the donor material or composition within the active layer or region 106 may be a polymer composition such as a low energy band gap polymer composition. For example, the donor composition may be a polymer having a band gap of less than 2 eV.

One non-limiting example of a donor material or composition is poly[4,8-bis(5-(2-ethylhexyl)thiophen-2-yl)benzo[1,2-b:4,5-b′]dithiophene-co-3-fluorothieno[3,4-b]thio-phene-2-carboxylate, or a derivative thereof. Another example of a low band gap polymer donor is poly[4,8-bis(5-(2-ethylhexyl)thiophen-2-yl)benzo[1,2-b;4,5-b′]dithiophene-2,6-diyl-alt-(4-(2-ethylhexyl)-3-fluorothieno[3,4-b]thiophene-)-2-carboxylate-2-6-diyl)](herein referred to as “PCE-10”), or a derivative thereof.

In another example, the donor is 2-[(7-{4-[N,N-Bis(4-methylphenyl)amino]phenyl}-2,1,3-benzothiadiazol-4-yl)methylene]propanedinitrile (herein referred to as “DTDCPB”), or a derivative thereof.

In another example, the donor includes 2-((7-(5-(dip-tolylamino)thiophen-21)benzo[c][1,2,5]thiadiazol-4-yl)methylene) malononitrile (herein referred to as “DTDCTB”).

Other non-limiting examples of low band gap polymer donors include the compounds depicted below in P1-P9, and their derivatives:

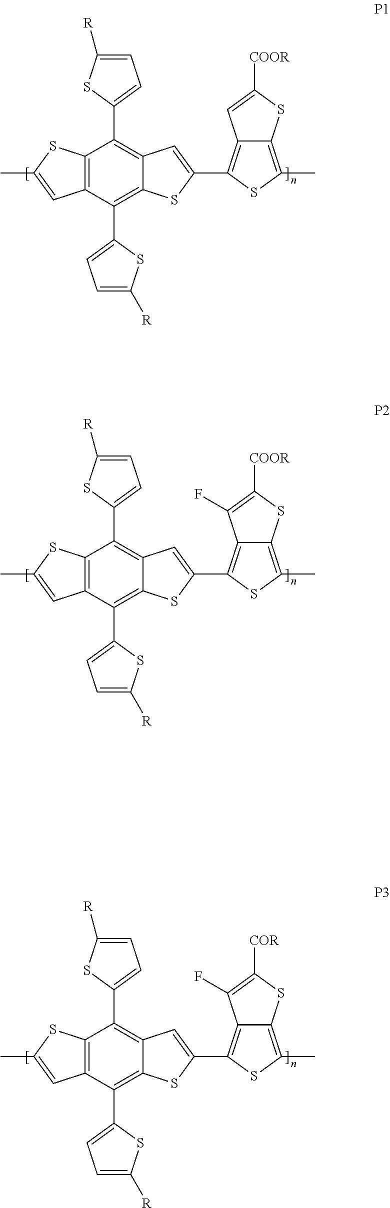

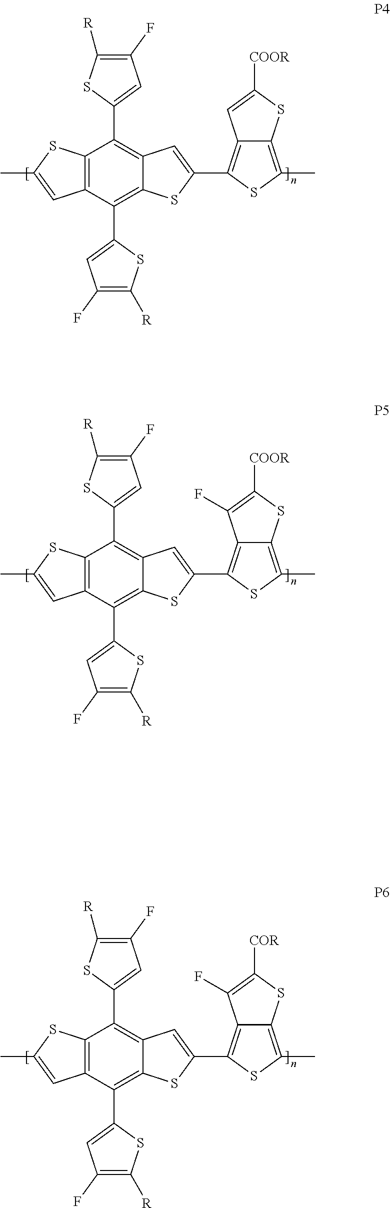

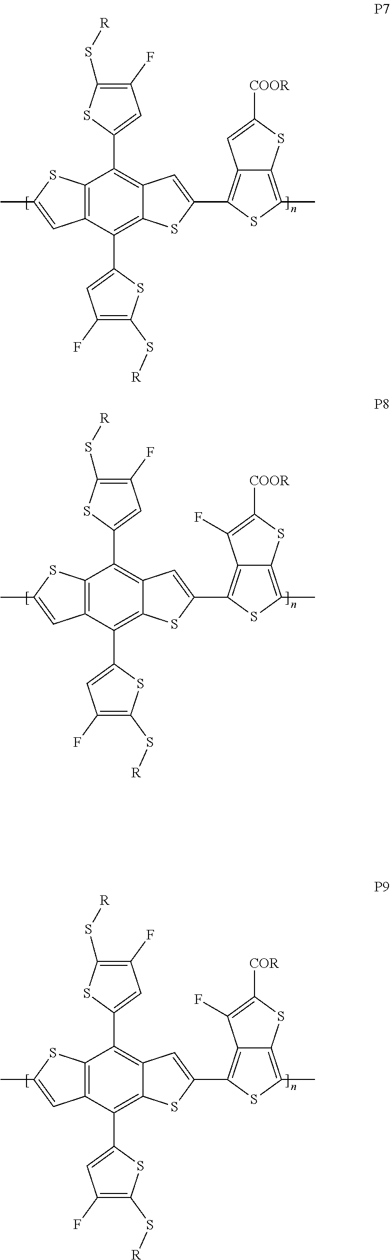

In the polymers depicted in P1-P9, n refers to the degree of polymerization. In some examples, n is within a range of 1-1000, 1-100, or 10-1000.

Additionally, R may represent a linear or branched saturated or unsaturated non-aromatic hydrocarbon, e.g., within the C₂-C₂₀ range. In certain examples, R represents a saturated hydrocarbon or alkyl group. Examples of linear or branched alkyl groups in the C₂-C₂₀ range include methyl, ethyl, n-propyl, isopropyl, isobutyl, n-butyl, sec-butyl, tert-butyl, isopentyl, n-pentyl, neopentyl, n-hexyl, and 2-ethylhexyl. In one particular example, R represents 2-ethylhexyl.

### Acceptor Composition

The acceptor in the active layer 106 may be a fullerene or non-fullerene acceptor molecule or composition. A fullerene molecule includes a hollow sphere, ellipsoid, or tube shape. The fullerene acceptor may be a spherical C₂₀, or C₂ₙ molecule, wherein n is an integer within a range of 12-100, for example. In certain examples, the fullerene acceptor is C₆₀ or C₇₀, or a derivative thereof.

In one embodiment, the active layer comprises a highly dipolar donor and a fullerene acceptor wherein the donor destabilizes the HOMO energy of the fullerene, thereby providing energetic confinement of electrons in the channel. In one embodiment, the highly dipolar donor comprises DTDCTB or DTDCPB. In one embodiment, the fullerene acceptor comprises C₆₀ or C₇₀.

Alternatively, the acceptor is a non-fullerene molecule. In such an example, the structure of the acceptor composition does not form a hollow sphere, ellipsoid, or tube. Non-limiting examples of the non-fullerene acceptor include:

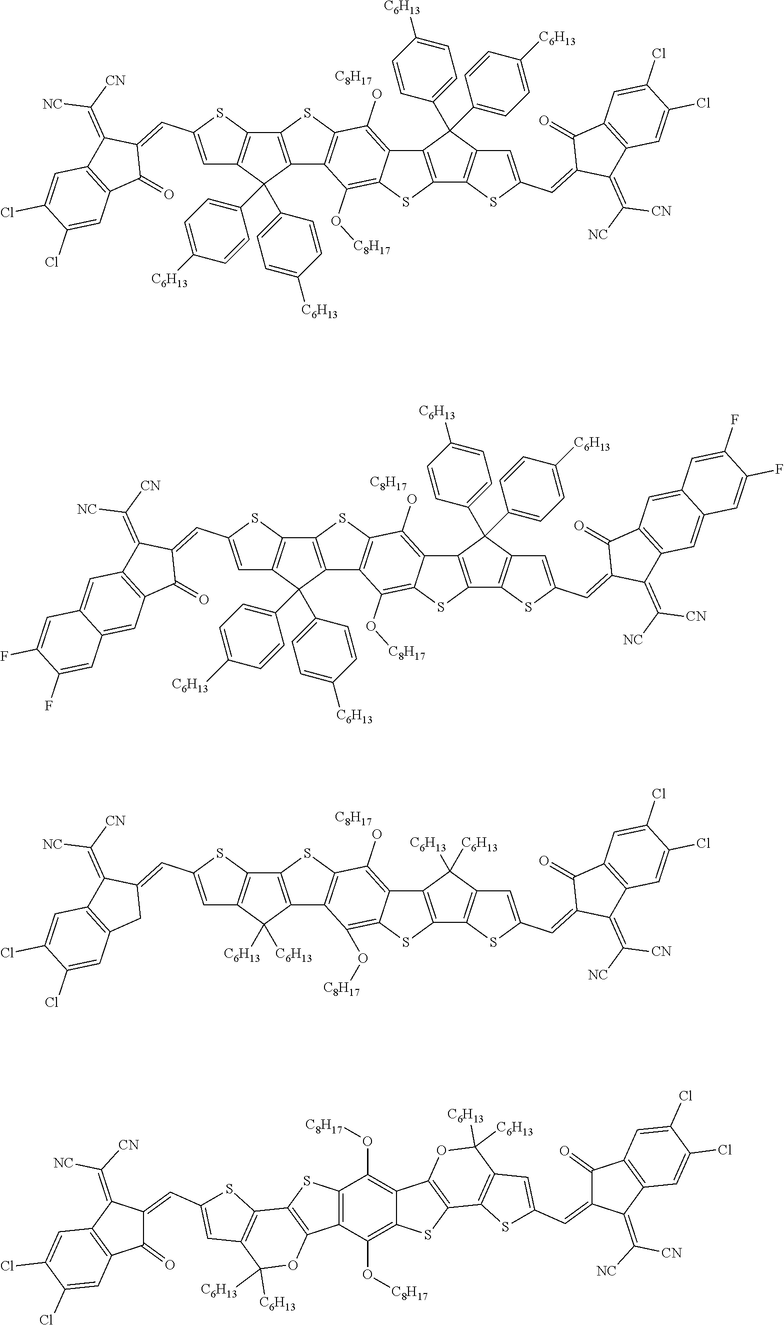

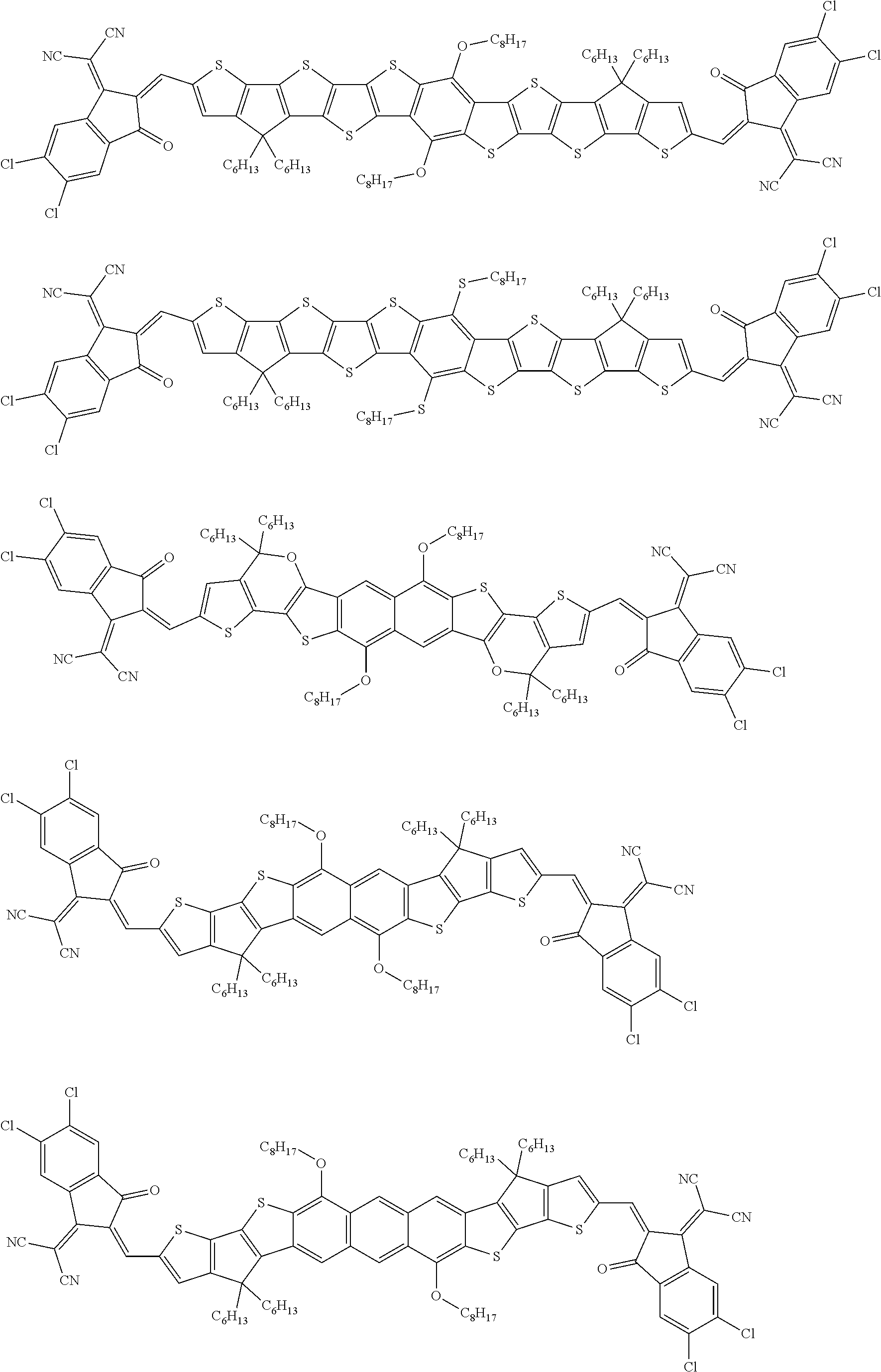

In one particular example, the non-fullerene acceptor is (4,4,10,10-tetrakis(4-hexylphenyl)-5,11-(2-ethylhexyloxy)-4,10-dihydro-dithienyl[1,2-b:4,5b′]benzodi-thiophene-2,8-diyl)bis(2-(3-oxo-2,3-dihydroinden-1-ylidene)malononitrile) (herein referred to as “BT-IC”). BT-IC has planar structure with a small torsion angle <1° and consequently, a high electron mobility. However, the absorption of BT-IC does not extend to wavelengths λ>850 nm. This leaves an unused part of the solar spectrum and a potential opening for further improvement in solar cell performance.

In another example, the non-fullerene acceptor is (4,4,10,10-tetrakis(4-hexylphenyl)-5,11-(2-ethylhexyloxy)-4,10-dihydro-dithienyl[1,2-b:4,5b′]benzodi-thiophene-2,8-diyl) bis(2-(3-oxo-2,3-dihydroinden-5,6-dichloro-1-ylidene) malononitrile (depicted in the structure below, herein referred to as “BT-CIC”). This structure provides a narrow absorption band confined to the near-infrared spectrum through the introduction of high electron affinity halogen atoms (e.g., chlorine atoms).

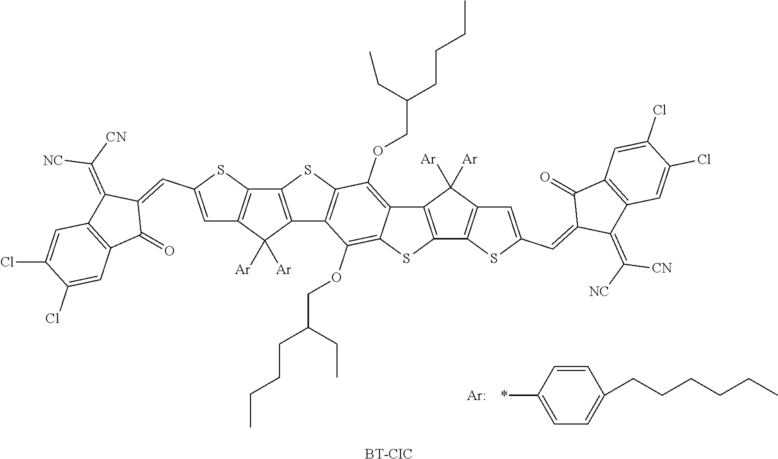

In this example, four chlorine atoms are positioned in the 5,6-positions of the 2-(3-oxo-2,3-dihydroinden-1-ylidene) malononitrile. The design is advantageous as it avoids significant issues of previously reported in chlorinated molecules with non-specific atomic site positioning (and hence property variability).

Such non-fullerene acceptor compositions disclosed herein provide certain improved characteristics over conventional acceptor compositions. For example, the NFAs disclosed herein may provide an increased electron density for the donor molecule; a reduced electron density for the acceptor molecule, and an increased conjugation length of the A-D-A molecule.

The electron-withdrawing halogen (e.g., Cl) atoms effectively lower the energy gap by enhancing the intramolecular charge transfer and delocalization of π-electrons into the unoccupied, atomic 3d orbitals. Moreover, the intermolecular interactions of Cl—S and Cl—Cl result in ordered molecular stacks in the donor-acceptor blend films.

In certain examples, the length of the non-fullerene acceptor may be at least 20 angstroms, 25 angstroms, 30 angstroms, 35 angstroms, 40 angstroms, 50 angstroms, or between 20-50 angstroms, 25-40 angstroms, or 25-35 angstroms.

### Three Dimensional (3D) Organic Framework

In one aspect, the present disclosure provides a three-dimensional (3D) organic framework, comprising a plurality of nodes, A; a plurality of linkers, B; and a plurality of interstitial void spaces, C. The 3D organic framework has a structure wherein each node of the plurality of nodes A is connected to at least another node of the plurality of nodes A through one of the plurality of linkers B; wherein each of the plurality of interstitial void spaces C can contain one or more molecules E; wherein at least one of A, B, or E is an electron donor; and wherein at least one of A, B, or E is an electron acceptor.

In some embodiment, none of the plurality of interstitial void spaces C contains E. In some embodiments, at least one of the plurality of interstitial void spaces C contains one or more molecules E. In some embodiments, the plurality of interstitial void spaces C contains two or more molecules E. In some such embodiments, the two or more molecules E may be the same or different. In some such embodiments, the two or more molecules E may be in the same void C space. In some such embodiments, the two or more molecules E may be in two or more different void C spaces. In some embodiments, one void C space can contain one and only molecule E. In some embodiments, each void C can contain one molecule E.

In some embodiments, the 3D organic framework is a metal-organic framework (MOF), wherein organic linkers connect the nodes of the framework which are comprised of metal ions or clusters. An example of a MOF node is the polyatomic metal oxide cluster Zr₆O₄(OH)₄.

In some embodiments, the 3D organic framework is a covalent-organic framework (COF), wherein organic linkers are covalently linked to the nodes of the framework. An example of a COF node is a tetrahedral carbon atom.

In some embodiments, the 3D organic framework has a unit cell.

In some embodiments, the unit cell is selected from a tetrahedron, a cube, an octahedron, an icosahedron, or a dodecahedron. As used herein, “unit cell” has its standard definition and includes a regular, repeating three-dimensional structure. In these embodiments, Nodes A are vertices of a polyhedron, and linkers B are edges of a polyhedron.

In some embodiments, the unit cell relates to the 3D structure formed by the connections between the plurality of nodes, A, and the plurality of linkers, B. In other words, in some embodiments, the unit cell is independent of the one or more molecules, E.

In some embodiments, the distribution of the one or more molecules, E, within the structure of the plurality of nodes, A, and the plurality of linkers, B, is not uniform. In other words, in some embodiments, there may be different numbers of the one or more molecules, E, in some unit cells, and the same number of the one or more molecules, E, in other unit cells.

In some embodiments, the distribution of the one or more molecules, E, within the structure of the plurality of nodes, A, and the plurality of linkers, B, is uniform. In other words, in some embodiments, there may be the same number of the one or more molecules, E, in each unit cell.

In some embodiments, the 3D organic framework is constructed such that the largest donor to acceptor (DTA) distance in a unit cell is less than the exciton diffusion length. The exciton diffusion length (LD) is a crucial parameter in organic semiconductors. It represents the characteristic distance that excitons (bound electron-hole pairs) can travel during their lifetime within a given material before they recombine.

In some embodiments, the 3D organic framework has a cube unit cell of Formula I shown in FIG. 1.

In some embodiments, at least two A's are the same in a unit cell.

In some embodiments, at least four A's are the same in a unit cell.

In some embodiments, each A is the same in a unit cell.

In some embodiments, at least two A's are different in a unit cell.

In some embodiments, at least two B's are the same in a unit cell.

In some embodiments, at least four B's are the same in a unit cell.

In some embodiments, each B is the same in a unit cell.

In some embodiments, at least two B's are different in a unit cell.

In some embodiments, there is exactly one E in a unit cell.

In some embodiments, at least two E's are present and are the same in a unit cell.

In some embodiments, at least two E's are present and are different in a unit cell.

In some embodiments, E when present is not chemically bonded to any A or B. In some embodiments, E when present is entrapped within the 3D organic framework. In some embodiments, one E when present extends between two adjacent unit cells.

In some of the foregoing embodiments, each unit cell in the 3D organic framework is the same. In some embodiments, there are at least two different unit cell structures within the 3D organic framework. In some embodiments, there are at least three different unit cell structures within the 3D organic framework. In some embodiments, there are at least four different unit cell structures within the 3D organic framework.

In some embodiments, one A is an acceptor, and B, E, or a different A is a donor.

In some embodiments, one B is an acceptor, and A, E, or a different B is a donor.

In some embodiments, one E is an acceptor, and A, B, or a different E is a donor.

In some embodiments, at least one B is an acceptor and at least one E or a different B is a donor. In some such embodiments, at least one E is a donor. In some such embodiments, a different B is a donor.

In some embodiments, at least one E is acceptor and at least one B or a different E is a donor. In some such embodiments, at least one B is a donor. In some such embodiments, a different E is a donor.

In some embodiments, E is present and is an acceptor and a different E is present and is a donor

In some embodiments, the plurality of linkers, B, are organic linkers.

In some embodiments, the one or more molecules, E when present, are organic molecules or organometallic complexes.

In some embodiments, the one or more molecules, E when present, are organic molecules.

In some embodiments, the one or more molecules, E when present, are organometallic complexes.

In some embodiments, the one or more molecules, E when present, occupy at least 25% of the plurality of interstitial void spaces. In some embodiments, the one or more molecules, E when present, occupy at least 50% of the plurality of interstitial void spaces. In some embodiments, the one or more molecules, E when present, occupy at least 75% of the plurality of interstitial void spaces. In some embodiments, the one or more molecules, E when present, occupy at least 90% of the plurality of interstitial void spaces.

In some embodiments, the one or more molecules, E when present, are the same.

In some embodiments, there are two or more molecules, E when present, that are different. In some embodiments, there are two or more molecules, E when present, that are different in the 3D organic framework. In some embodiments, there are two or more molecules, E, that are different in the same unit cell.

In some embodiments, the electron donor may have a core structure selected from the group consisting of the following:

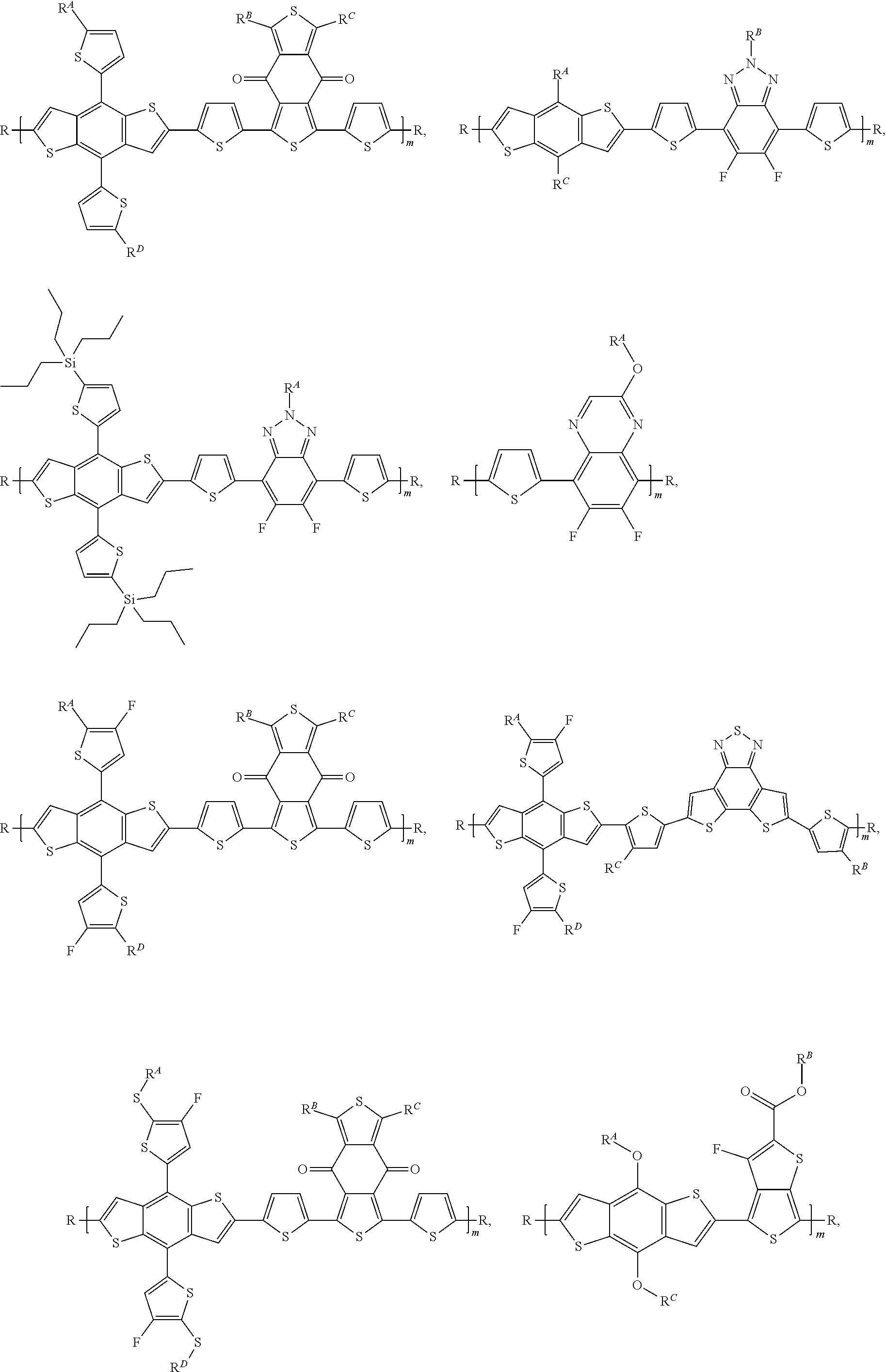

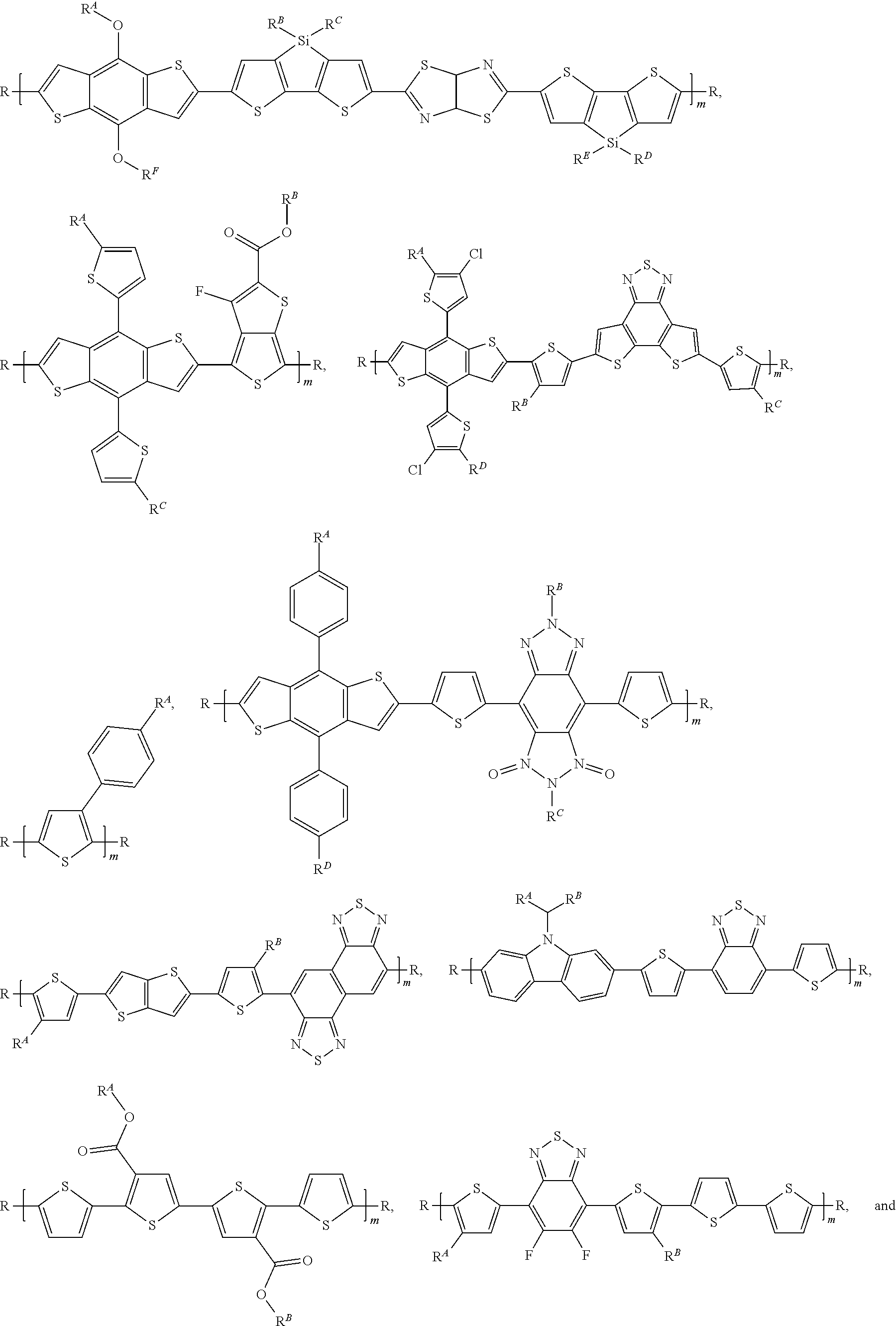

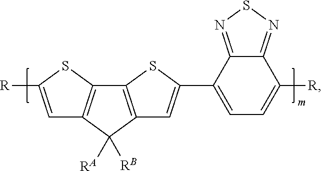

wherein m is an integer from 1 to 5;
wherein each R is independently selected from the group consisting of

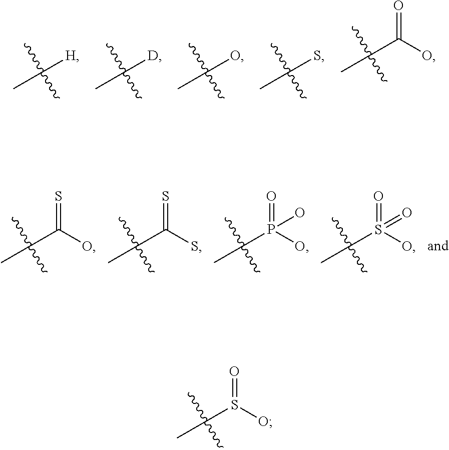

wherein each of R^{A}, R^{B}, R^{C}, R^{D}, R^{E}, and R^{F} independently represents a linear or branched saturated or unsaturated non-aromatic hydrocarbon, e.g., within the C₂-C₂₂ range. In certain examples, each of R^{A}, R^{B}, R^{C}, R^{D}, R^{E}, and R^{F} independently represents a saturated hydrocarbon or alkyl group. Examples of linear or branched alkyl groups in the C₂-C₂₂ range include methyl, ethyl, n-propyl, isopropyl, isobutyl, n-butyl, sec-butyl, tert-butyl, isopentyl, n-pentyl, neopentyl, n-hexyl, and 2-ethylhexyl. In some examples, each of R^{A}, R^{B}, R^{C}, R^{D}, R^{E}, and R^{F} independently represents 2-ethylhexyl, C₄H₉, C₆H₁₃, C₈H₁₇, C₁₀H₂₁, C₁₂H₂₅, C₁₆H₃₃, C₁₈H₃₇, or C₂₀H₄₁.

In some embodiments, the electron donor has a core structure selected from the group consisting of:

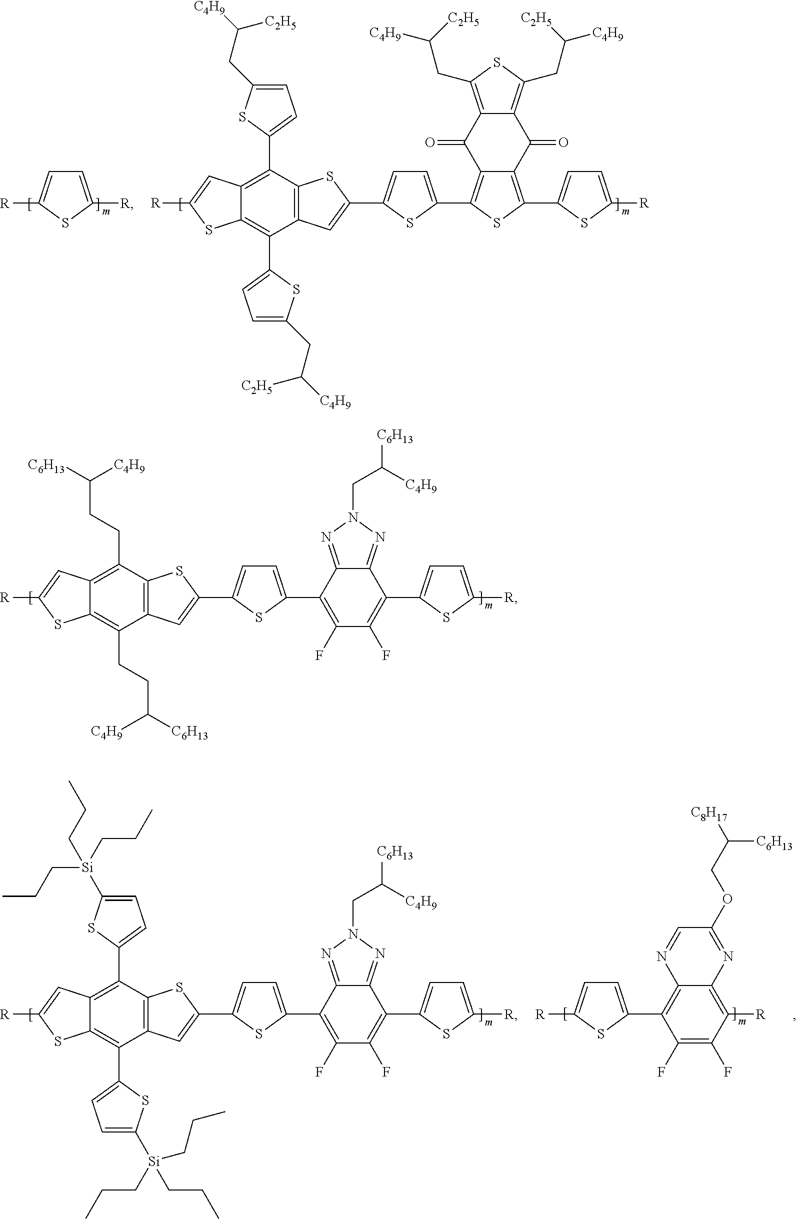

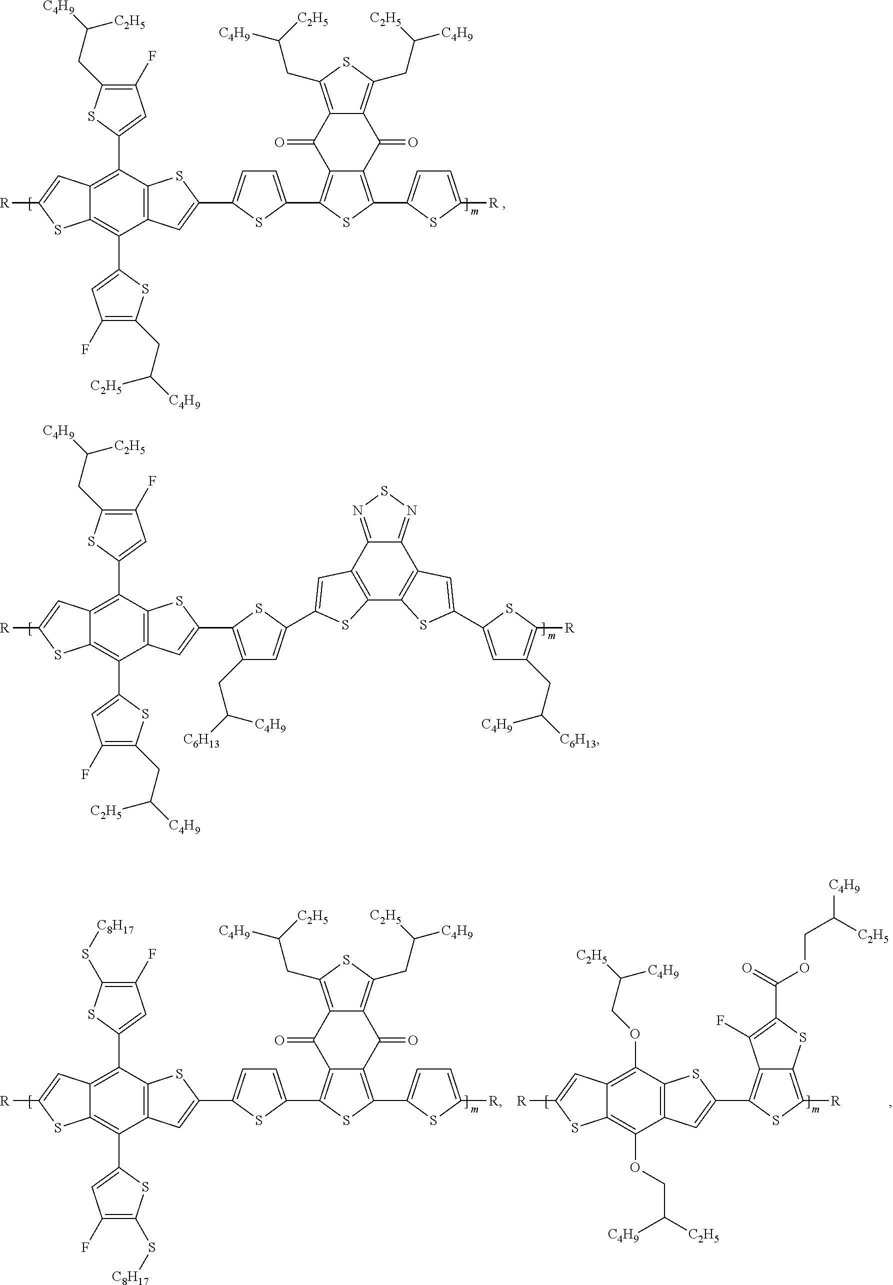

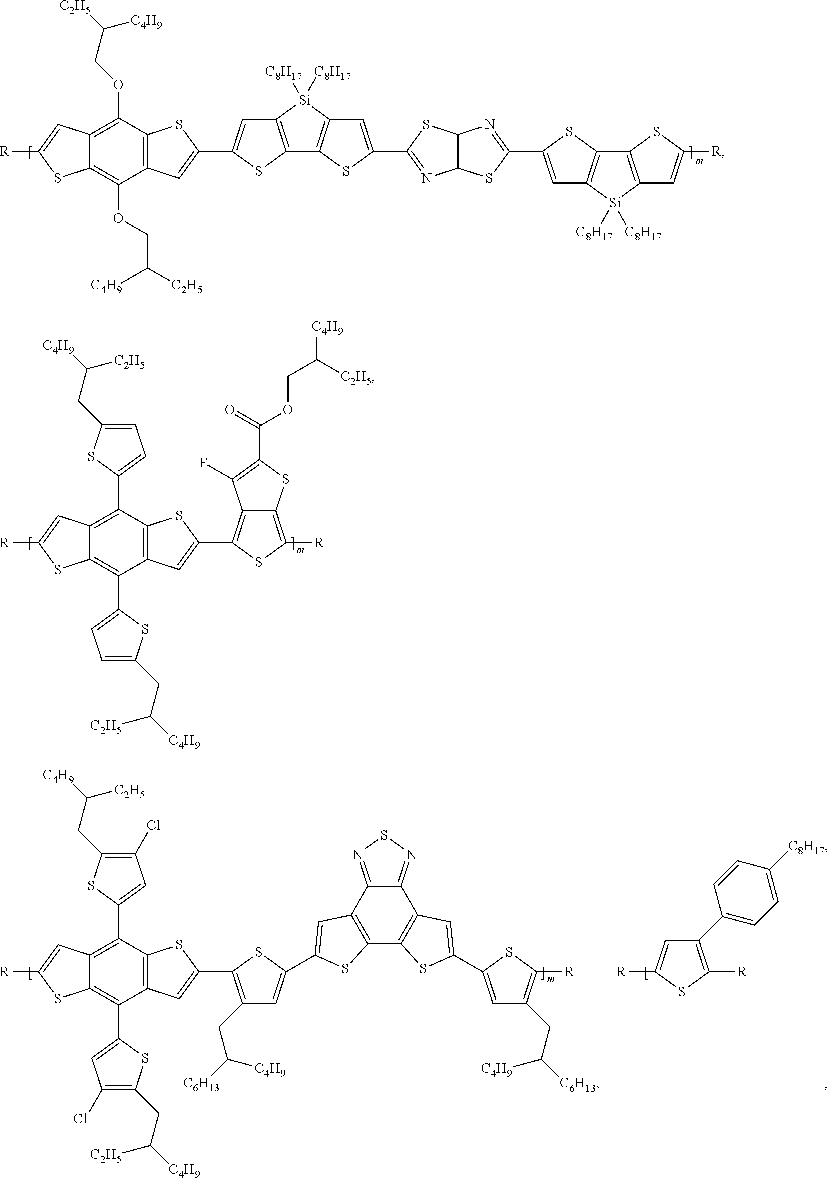

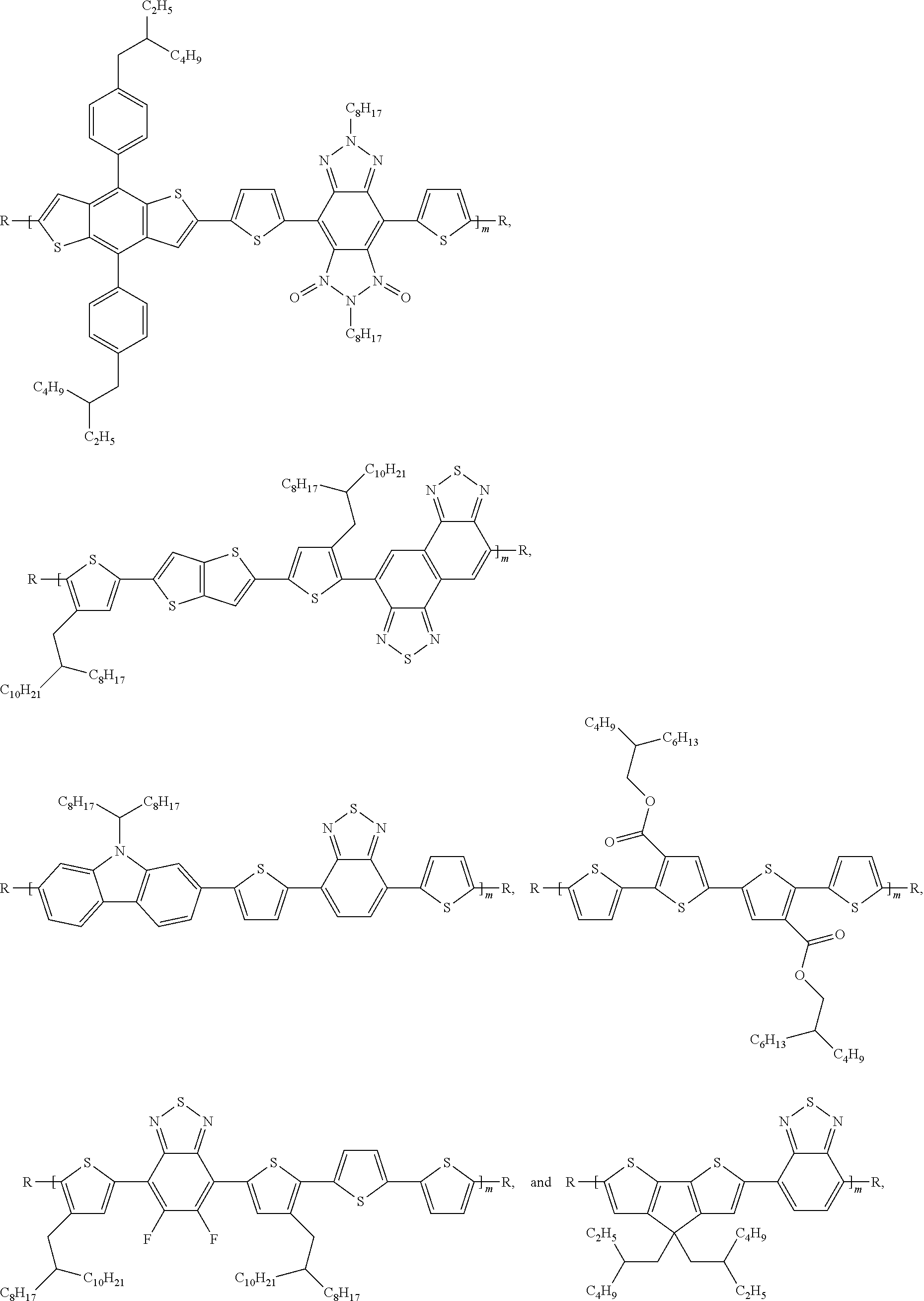

wherein m is an integer from 1 to 5; and
wherein each R is independently selected from the group consisting of

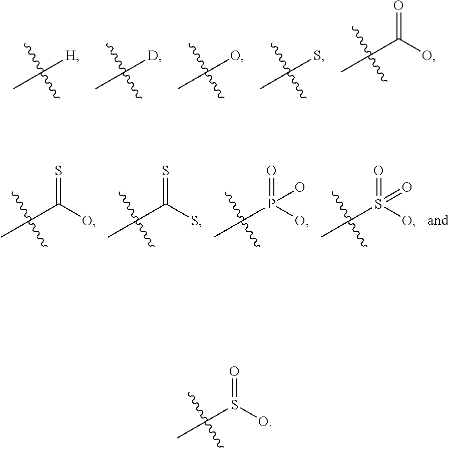

In some of the above embodiments, m is 1. In some embodiments, m is 2. In some embodiments, m is 3. In some embodiments, m is 4. In some embodiments, m is 5.

In some embodiments, the electron acceptor has a core structure selected from the group consisting of:

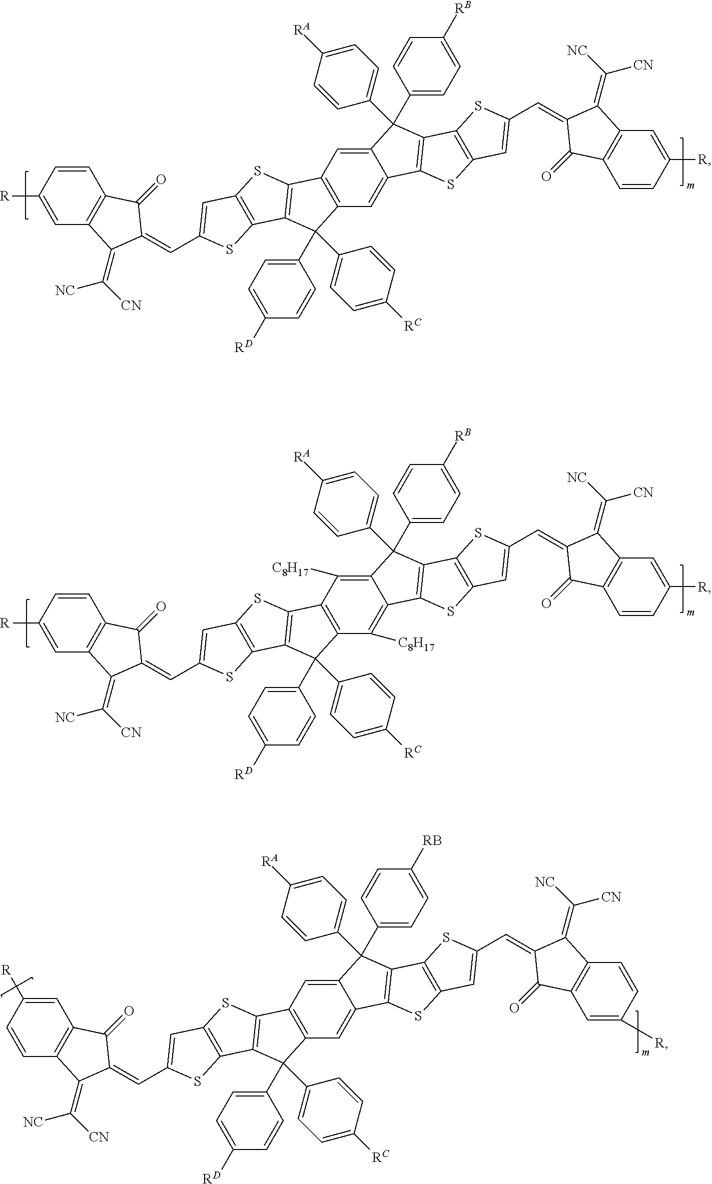

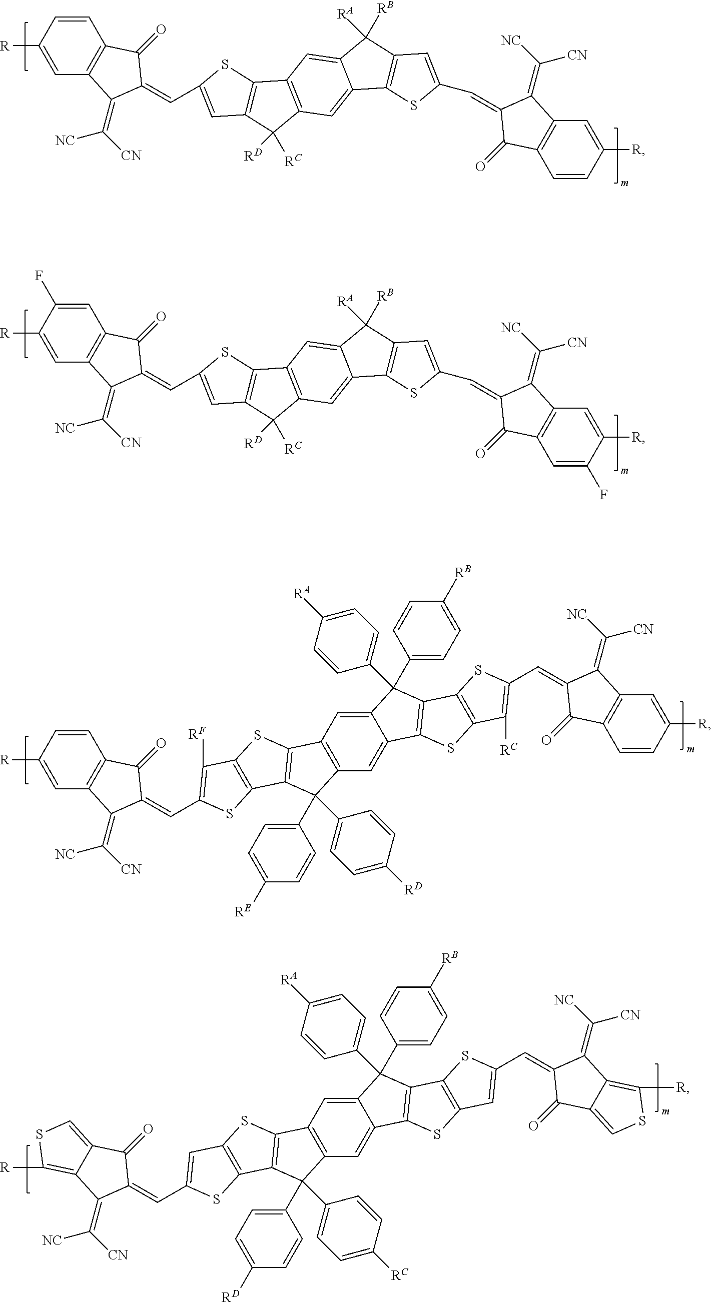

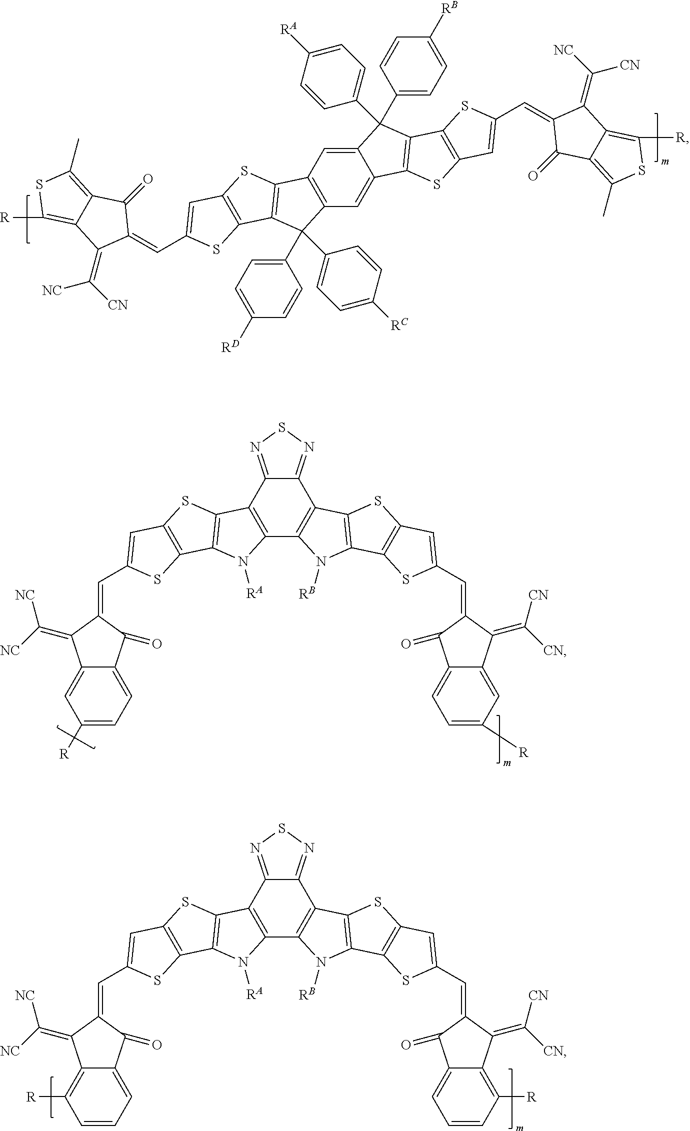

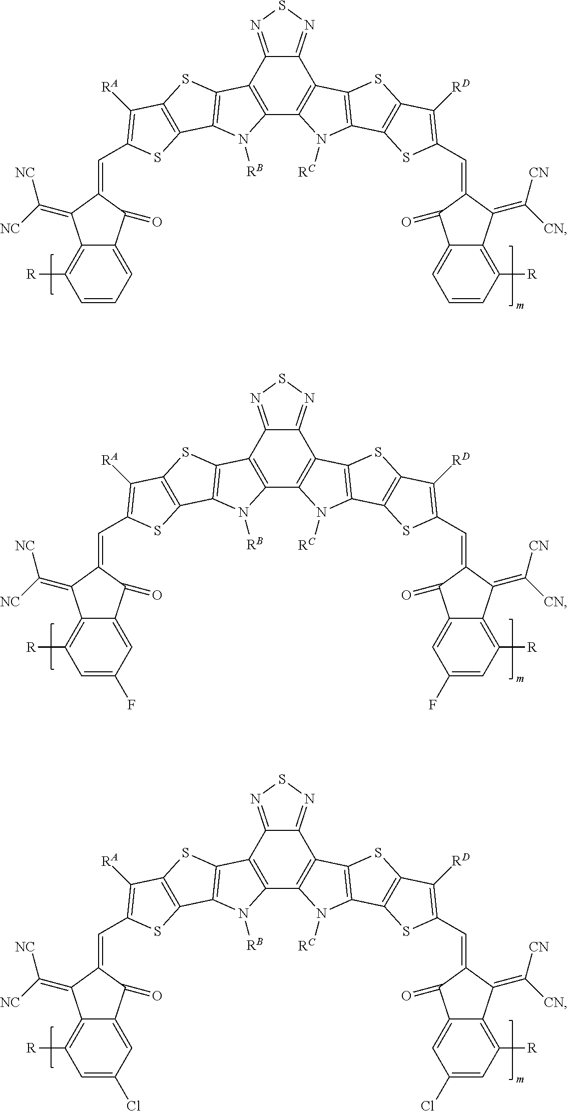

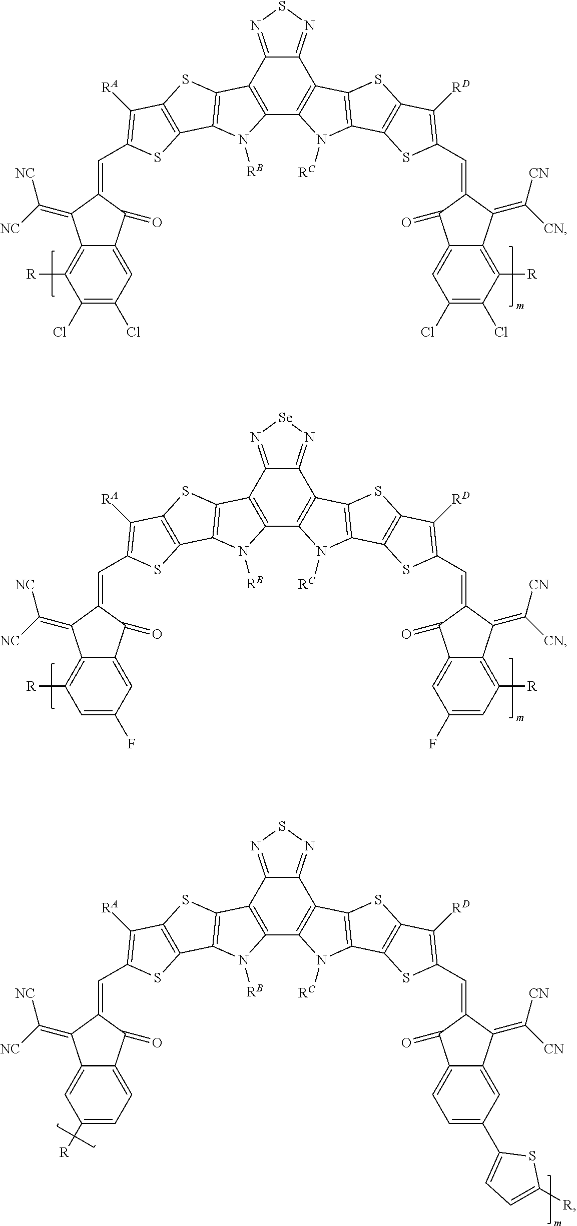

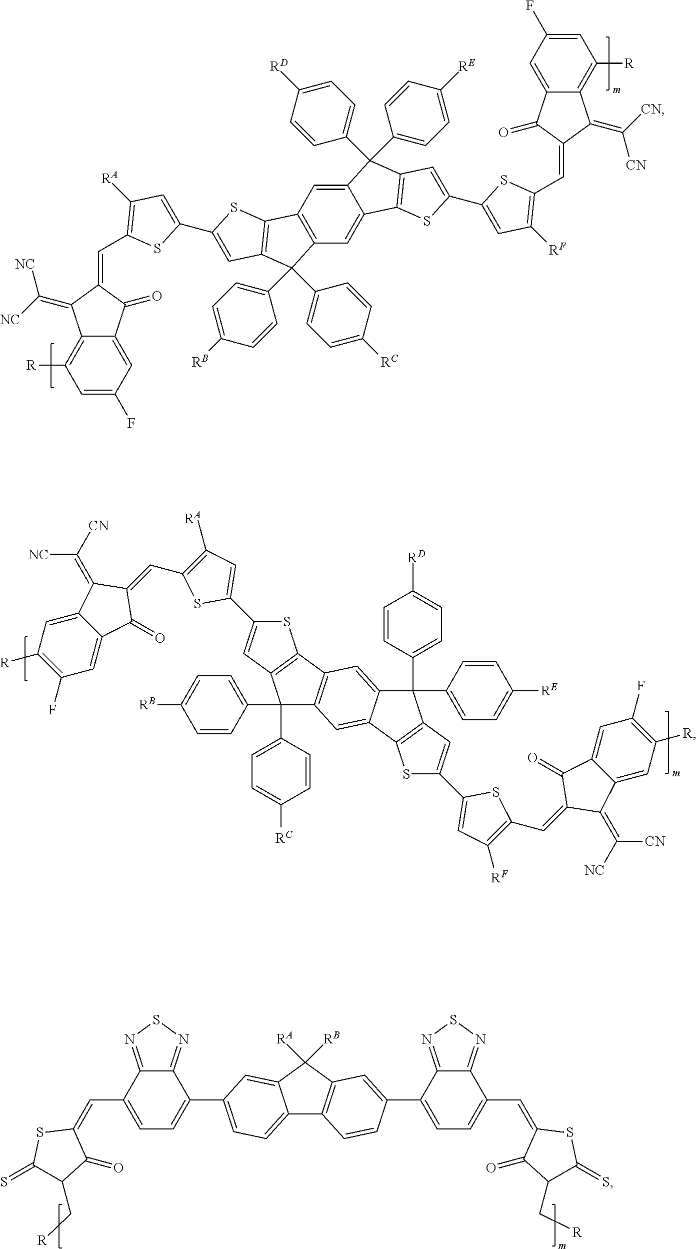

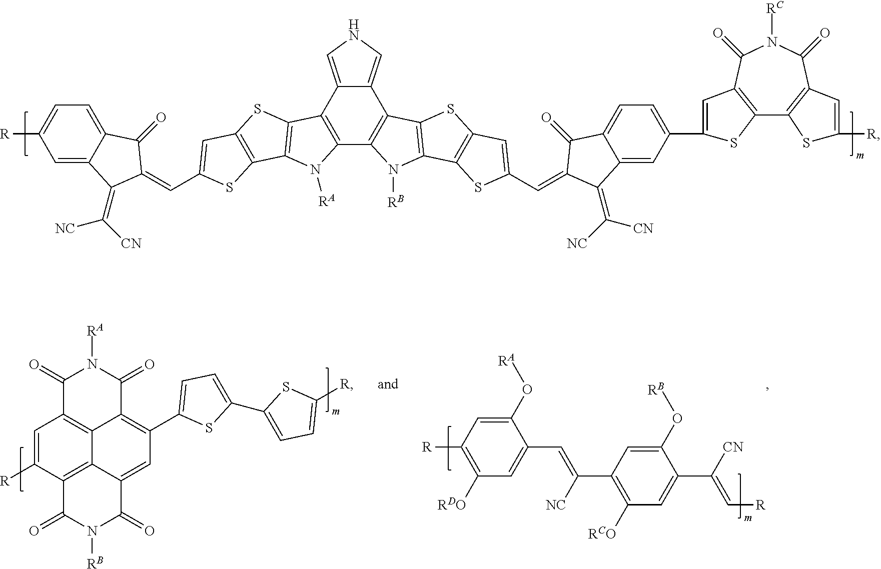

wherein m is an integer from 1 to 5; wherein each R is independently selected from the group consisting of

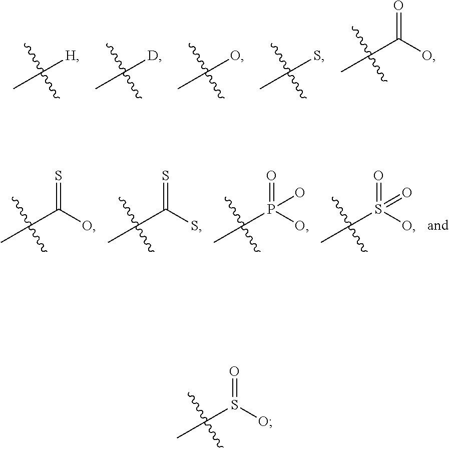

and R^{A}, R^{B}, R^{C}, R^{D}, R^{E}, and R^{F} are the same as previous defined.

In some embodiments, the electron acceptor has a core structure selected from the group consisting of:

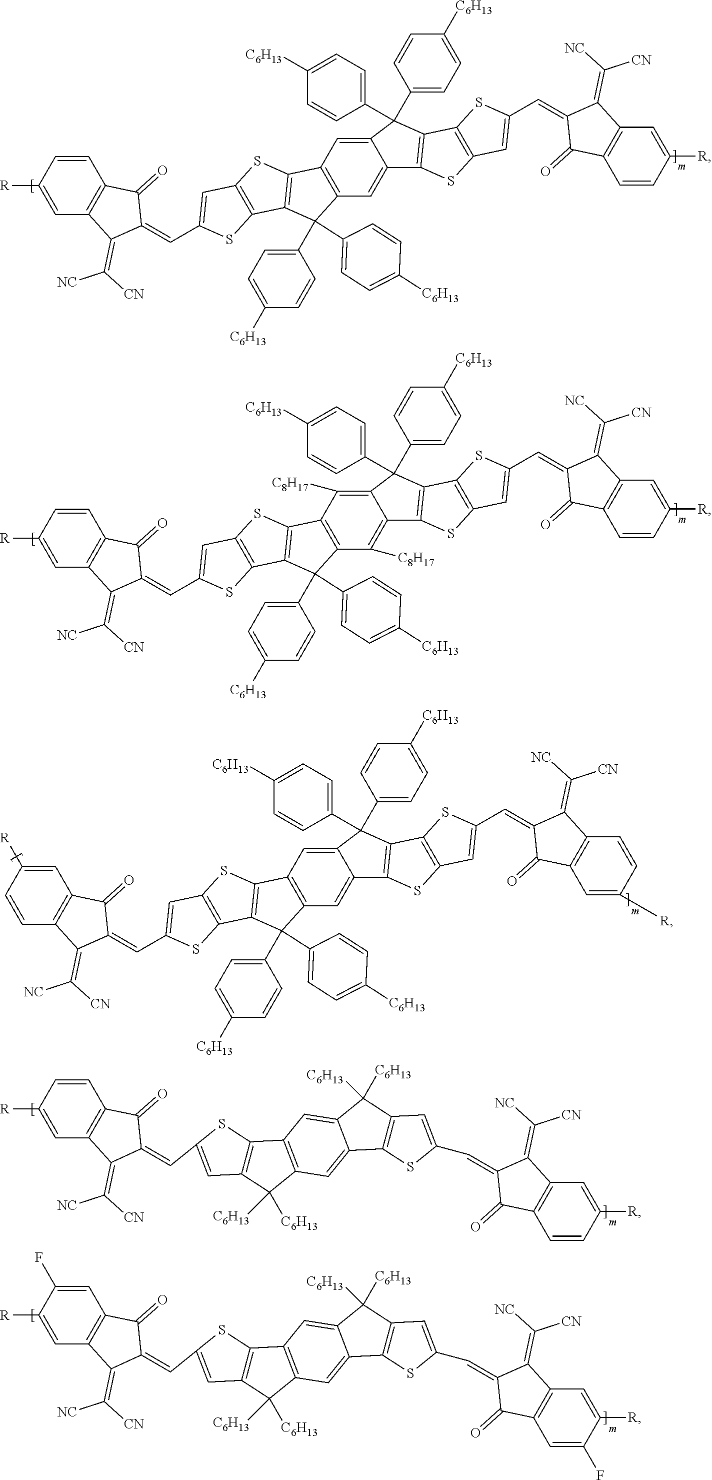

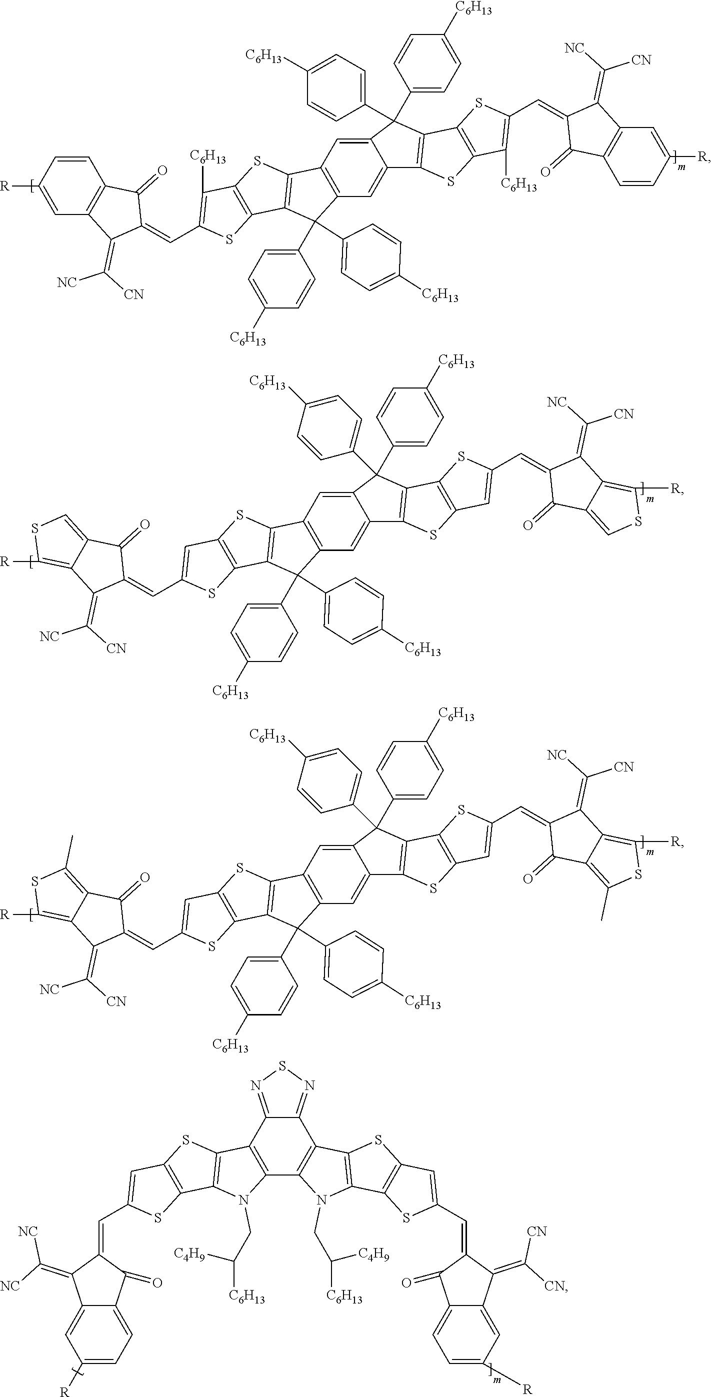

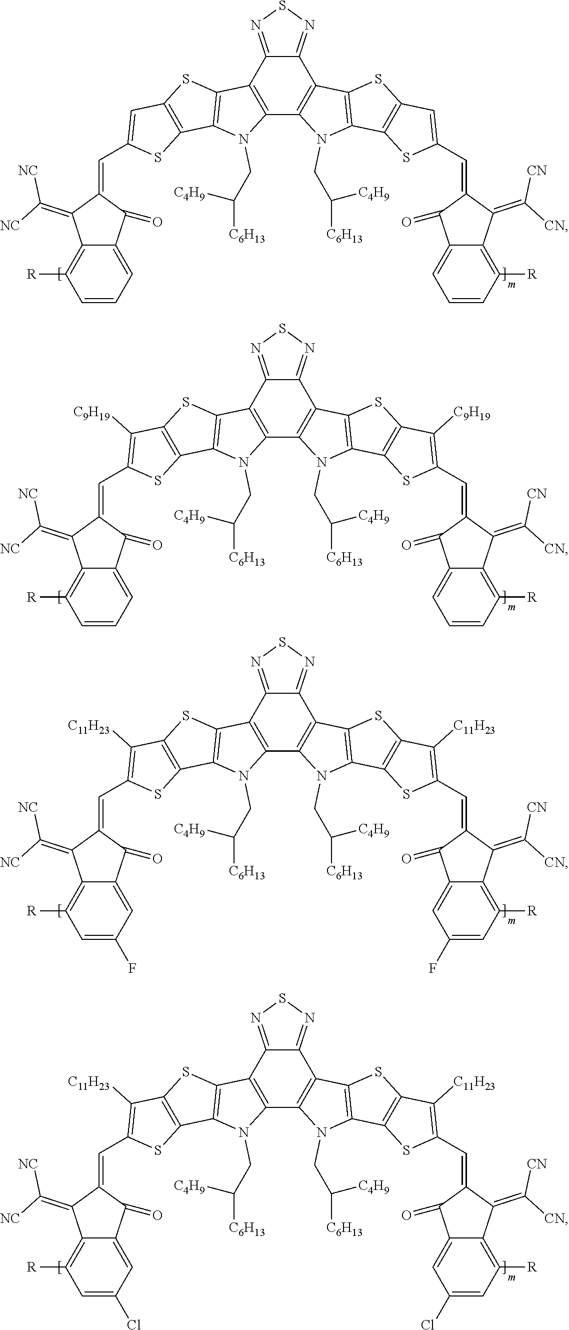

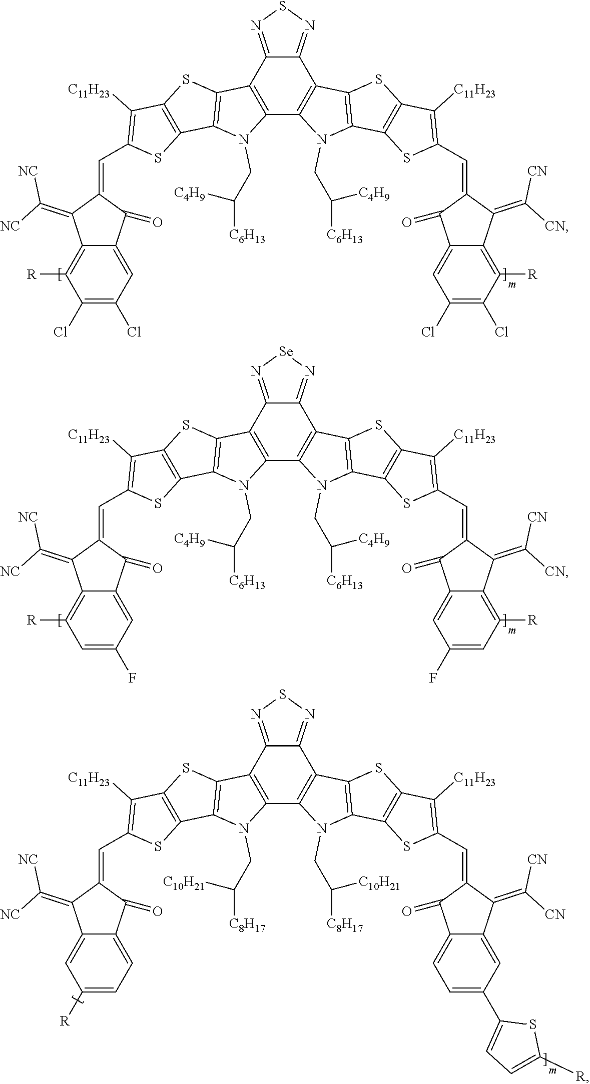

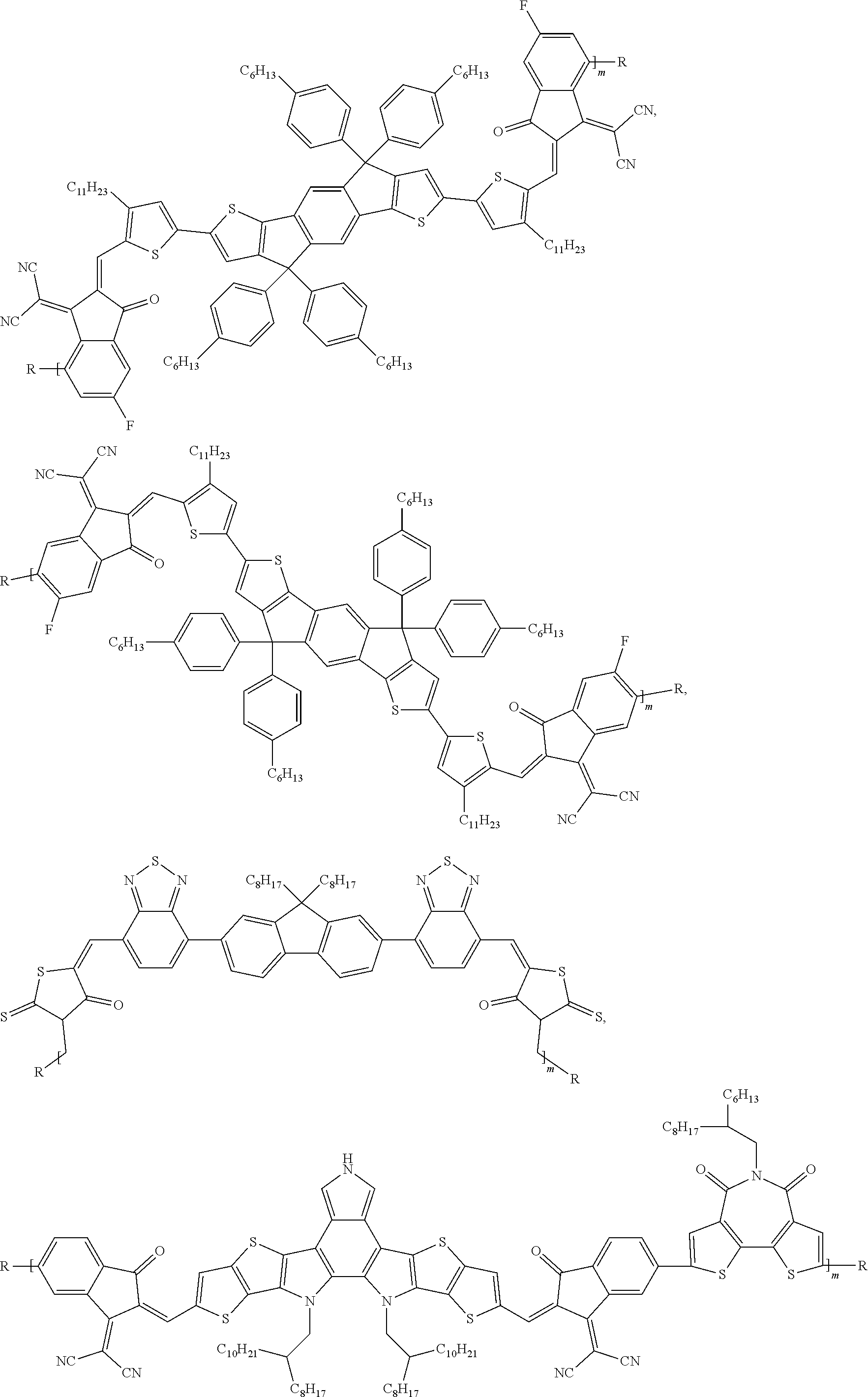

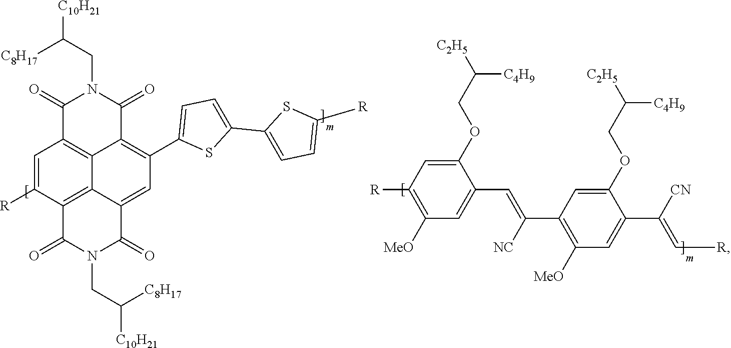

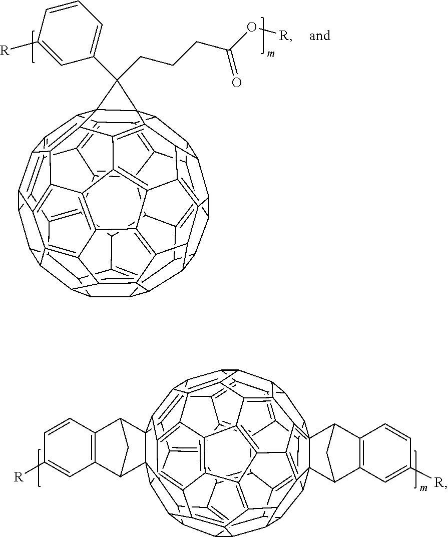

wherein m is an integer from 1 to 5; wherein each R is independently selected from the group consisting of

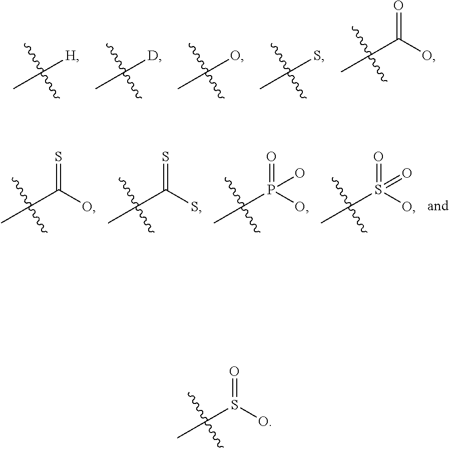

In some of the above embodiments, m is 1. In some embodiments, m is 2. In some embodiments, m is 3. In some embodiments, m is 4. In some embodiments, m is 5.

As used in the foregoing structures,

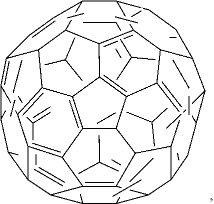

represents a buckminsterfullerene (C₆₀).

In some embodiments when one or more of molecules E or E2 are present in the void spaces C or C2, the one or more of molecules E or E2 may be any one of the electron donors or electron acceptors as described herein. They may be neutral or charged molecules, but generally not covalently bonded to either a node or a linker.

Formulations comprising the 3D organic framework are also provided.

In some embodiments, at least one of nodes A, a plurality of linkers B, or one or more molecules E as described herein is partially or fully deuterated. In some embodiments, at least one of nodes A, a plurality of linkers B, or one or more molecules E as described herein is fully deuterated. In some embodiments, at least one of nodes A, a plurality of linkers B, or one or more molecules E as described herein can be at least 30% deuterated, at least 40% deuterated, at least 50% deuterated, at least 60% deuterated, at least 70% deuterated, at least 80% deuterated, at least 90% deuterated, at least 95% deuterated, at least 99% deuterated, or 100% deuterated. As used herein, percent deuteration has its ordinary meaning and includes the percentage of possible hydrogen atoms (e.g., positions that are hydrogen or deuterium) that are replaced by deuterium atoms.

In some embodiments, at least one of nodes A as described herein is partially or fully deuterated. In some embodiments, at least one of nodes A as described herein is fully deuterated. In some embodiments, at least one of nodes A as described herein can be at least 30% deuterated, at least 40% deuterated, at least 50% deuterated, at least 60% deuterated, at least 70% deuterated, at least 80% deuterated, at least 90% deuterated, at least 95% deuterated, at least 99% deuterated, or 100% deuterated.

In some embodiments, all nodes A as described herein are each partially or fully deuterated. In some embodiments, all nodes A as described herein are each fully deuterated. In some embodiments, all nodes A as described herein can be each at least 30% deuterated, at least 40% deuterated, at least 50% deuterated, at least 60% deuterated, at least 70% deuterated, at least 80% deuterated, at least 90% deuterated, at least 95% deuterated, at least 99% deuterated, or 100% deuterated.

In some embodiments, at least one of a plurality of linkers B as described herein is partially or fully deuterated. In some embodiments, at least one of a plurality of linkers B as described herein is fully deuterated. In some embodiments, at least one of a plurality of linkers B as described herein can be at least 30% deuterated, at least 40% deuterated, at least 50% deuterated, at least 60% deuterated, at least 70% deuterated, at least 80% deuterated, at least 90% deuterated, at least 95% deuterated, at least 99% deuterated, or 100% deuterated.

In some embodiments, all of a plurality of linkers B as described herein are each partially or fully deuterated. In some embodiments, all of a plurality of linkers B as described herein are each fully deuterated. In some embodiments, all of a plurality of linkers B as described herein can be each at least 30% deuterated, at least 40% deuterated, at least 50% deuterated, at least 60% deuterated, at least 70% deuterated, at least 80% deuterated, at least 90% deuterated, at least 95% deuterated, at least 99% deuterated, or 100% deuterated.

In some embodiments, at least one of one or more molecules E as described herein is partially or fully deuterated. In some embodiments, at least one of one or more molecules E as described herein is fully deuterated. In some embodiments, at least one of one or more molecules E as described herein can be at least 30% deuterated, at least 40% deuterated, at least 50% deuterated, at least 60% deuterated, at least 70% deuterated, at least 80% deuterated, at least 90% deuterated, at least 95% deuterated, at least 99% deuterated, or 100% deuterated.

In some embodiments, all of one or more molecules E as described herein are each partially or fully deuterated. In some embodiments, all of one or more molecules E as described herein are each fully deuterated. In some embodiments, all of one or more molecules E as described herein can be each at least 30% deuterated, at least 40% deuterated, at least 50% deuterated, at least 60% deuterated, at least 70% deuterated, at least 80% deuterated, at least 90% deuterated, at least 95% deuterated, at least 99% deuterated, or 100% deuterated.

In some embodiments, at least one of nodes A2, a plurality of linkers B2, or one or more molecules E2, as described herein is partially or fully deuterated. In some embodiments, at least one of nodes A2, a plurality of linkers B2, or one or more molecules E2 as described herein is fully deuterated. In some embodiments, at least one of nodes A2, a plurality of linkers B2, or one or more molecules E2 as described herein can be at least 30% deuterated, at least 40% deuterated, at least 50% deuterated, at least 60% deuterated, at least 70% deuterated, at least 80% deuterated, at least 90% deuterated, at least 95% deuterated, at least 99% deuterated, or 100% deuterated.

In some embodiments, at least one of nodes A2 as described herein is partially or fully deuterated. In some embodiments, at least one of nodes A2 as described herein is fully deuterated. In some embodiments, at least one of nodes A2 as described herein can be at least 30% deuterated, at least 40% deuterated, at least 50% deuterated, at least 60% deuterated, at least 70% deuterated, at least 80% deuterated, at least 90% deuterated, at least 95% deuterated, at least 99% deuterated, or 100% deuterated.

In some embodiments, all nodes A2 as described herein are each partially or fully deuterated. In some embodiments, all nodes A2 as described herein are each fully deuterated. In some embodiments, all nodes A2 as described herein can be each at least 30% deuterated, at least 40% deuterated, at least 50% deuterated, at least 60% deuterated, at least 70% deuterated, at least 80% deuterated, at least 90% deuterated, at least 95% deuterated, at least 99% deuterated, or 100% deuterated.

In some embodiments, at least one of a plurality of linkers B2 as described herein is partially or fully deuterated. In some embodiments, at least one of a plurality of linkers B2 as described herein is fully deuterated. In some embodiments, at least one of a plurality of linkers B2 as described herein can be at least 30% deuterated, at least 40% deuterated, at least 50% deuterated, at least 60% deuterated, at least 70% deuterated, at least 80% deuterated, at least 90% deuterated, at least 95% deuterated, at least 99% deuterated, or 100% deuterated.

In some embodiments, all of a plurality of linkers B2 as described herein are each partially or fully deuterated. In some embodiments, all of a plurality of linkers B2 as described herein are each fully deuterated. In some embodiments, all of a plurality of linkers B2 as described herein can be each at least 30% deuterated, at least 40% deuterated, at least 50% deuterated, at least 60% deuterated, at least 70% deuterated, at least 80% deuterated, at least 90% deuterated, at least 95% deuterated, at least 99% deuterated, or 100% deuterated.

In some embodiments, at least one of one or more molecules E2 as described herein is partially or fully deuterated. In some embodiments, at least one of one or more molecules E2 as described herein is fully deuterated. In some embodiments, at least one of one or more molecules E2 as described herein can be at least 30% deuterated, at least 40% deuterated, at least 50% deuterated, at least 60% deuterated, at least 70% deuterated, at least 80% deuterated, at least 90% deuterated, at least 95% deuterated, at least 99% deuterated, or 100% deuterated.

In some embodiments, all of one or more molecules E2 as described herein are each partially or fully deuterated. In some embodiments, all of one or more molecules E2 as described herein are each fully deuterated. In some embodiments, all of one or more molecules E2 as described herein can be each at least 30% deuterated, at least 40% deuterated, at least 50% deuterated, at least 60% deuterated, at least 70% deuterated, at least 80% deuterated, at least 90% deuterated, at least 95% deuterated, at least 99% deuterated, or 100% deuterated.

### Channel Layer

As noted above, the OPV may include a channel layer 112 positioned between the active layer and an electrode (e.g., the electrode grid). In one embodiment, the OPV comprises a channel layer 112 positioned between the active layer and the buffer layer. In one embodiment, the OPV comprises a channel layer positioned between an electron blocking layer and a heterojunction (HJ). In one embodiment, the OPV comprises a channel layer positioned between an electron blocking layer and a blended donor:fullerene HJ that generates charge by dissociating excitons. In one embodiment, the blended donor:fullerene HJ comprises C₇₀. The blended donor:fullerene HJ may comprise any donor described elsewhere herein or known in the art. The channel layer 112 is configured to laterally disperse a charge across the channel layer, for example in a direction orthogonal to the thickness of the channel layer.

The channel layer 112 may include a composition having a high diffusivity/mobility, sufficient energy barrier (order of a few hundred meV) preventing charges from hopping into adjacent layers, energy levels that prevent the opposite charge carrier from hopping into the channel, as well as very low trap and defect densities in its bulk and at its interfaces. When these conditions are met, long range lateral transport is possible. This enables OPV devices using lateral transport layers.

In an embodiment wherein the channel layer is positioned between an active layer and a buffer layer, the energy barrier between the channel layer and the active layer confines electrons to the channel layer. In an embodiment wherein the channel layer is positioned between an electron blocking layer and a HJ, the energy barrier between the channel layer and the HJ confines electrons to the channel layer, spatially separating them from photogenerated holes in the HJ. In one embodiment, an energy barrier at the channel/HJ interface of between about 0.1 eV and about 5 eV confines electrons within the channel. In one embodiment, an energy barrier at the channel/HJ interface of between about 0.1 eV and about 4.5 eV confines electrons within the channel. In one embodiment, an energy barrier at the channel/HJ interface of between about 0.1 eV and about 4 eV confines electrons within the channel. In one embodiment, an energy barrier at the channel/HJ interface of between about 0.1 eV and about 3.5 eV confines electrons within the channel. In one embodiment, an energy barrier at the channel/HJ interface of between about 0.1 eV and about 3 eV confines electrons within the channel. In one embodiment, an energy barrier at the channel/HJ interface of between about 0.1 eV and about 2.5 eV confines electrons within the channel. In one embodiment, an energy barrier at the channel/HJ interface of between about 0.1 eV and about 2 eV confines electrons within the channel. In one embodiment, an energy barrier at the channel/HJ interface of between about 0.1 eV and about 1 eV confines electrons within the channel. In one embodiment, an energy barrier at the channel/HJ interface of between about 0.2 eV and about 0.7 eV confines electrons within the channel. In one embodiment, an energy barrier at the channel/HJ interface of about 0.42±0.1 eV confines electrons within the channel. As a result of this energetic confinement and exceptionally low trap densities within the channel and along its interfaces, centimeter-scale diffusion of electrons is observed in the channel.

In one embodiment, the charge diffusion length in an OPV comprising a fullerene channel is greater than about 1 cm. In one embodiment, the charge diffusion length in an OPV comprising a fullerene channel is greater than about 2 cm. In one embodiment, the charge diffusion length in an OPV comprising a fullerene channel is greater than about 3 cm. In one embodiment, the charge diffusion length in an OPV comprising a fullerene channel is greater than about 3.5 cm. In one embodiment, the charge diffusion length in an OPV comprising a fullerene channel is greater than the device length.

In one embodiment, an OPV comprising a fullerene channel has a room temperature (RT) charge diffusivity of between about 0.05 cm²s⁻¹ and about 10 cm²s⁻¹. In one embodiment, an OPV comprising a fullerene channel has an RT charge diffusivity of between about 0.05 cm²s⁻¹ and about 9 cm²s⁻¹. In one embodiment, an OPV comprising a fullerene channel has an RT charge diffusivity of between about 0.05 cm²s⁻¹ and about 8 cm²s⁻¹. In one embodiment, an OPV comprising a fullerene channel has an RT charge diffusivity of between about 0.05 cm²s⁻¹ and about 7 cm²s⁻¹. In one embodiment, an OPV comprising a fullerene channel has an RT charge diffusivity of between about 0.05 cm²s⁻¹ and about 6 cm²s⁻¹. In one embodiment, an OPV comprising a fullerene channel has an RT charge diffusivity of between about 0.05 cm²s⁻¹ and about 5 cm²s⁻¹. In one embodiment, an OPV comprising a fullerene channel has a charge diffusivity of between about 0.05 cm²s⁻¹ and about 4 cm²s⁻¹. In one embodiment, an OPV comprising a fullerene channel has an RT charge diffusivity of between about 0.05 cm²s⁻¹ and about 3 cm²s⁻¹. In one embodiment, an OPV comprising a fullerene channel has an RT charge diffusivity of between about 0.05 cm²s⁻¹ and about 2 cm²s⁻¹. In one embodiment, an OPV comprising a fullerene channel has an RT charge diffusivity of between about 0.05 cm²s⁻¹ and about 1.5 cm²s⁻¹. In one embodiment, an OPV comprising a fullerene channel has an RT charge diffusivity of between about 0.1 cm²s⁻¹ and about 1.5 cm²s⁻¹. In one embodiment, an OPV comprising a C₆₀ fullerene channel has an RT charge diffusivity of about 0.67±0.06 cm²s⁻¹. In one embodiment, an OPV comprising a C₇₀ fullerene channel has an RT charge diffusivity of about 0.16±0.01 cm²s⁻¹.

In one embodiment, the charge diffusivity of the device comprising a fullerene channel is thermally activated. In one embodiment, the activation energy is between about 5 meV and about 200 meV. In one embodiment, the activation energy is between about 5 meV and about 180 meV. In one embodiment, the activation energy is between about 5 meV and about 160 meV. In one embodiment, the activation energy is between about 5 meV and about 140 meV. In one embodiment, the activation energy is between about 5 meV and about 120 meV. In one embodiment, the activation energy is between about 5 meV and about 100 meV. In one embodiment, the activation energy is between about 5 meV and about 90 meV. In one embodiment, the activation energy is between about 15 meV and about 90 meV. In one embodiment, the activation energy is between about 25 meV and about 90 meV. In one embodiment, the activation energy of a device comprising a neat C₆₀ fullerene channel is about 70±8 meV. In one embodiment, the activation energy of a device comprising a neat C₇₀ fullerene channel is about 36±3 meV.

Due to the presence of the channel layer 112, the OPV device 100 may generate current in response to photons incident on the areas between cathode/anode overlap (e.g., off the grid). In one embodiment, an OPV device including the disclosed channel layer has a significant photocurrent response to light absorbed >1 cm beyond its collecting contact. In one embodiment, the device has a photocurrent response of at least 5% at a distance of 1 cm beyond its collecting contact. In other embodiments, the photocurrent response is at least 10%, at least 12%, or at least 15%. This device may be illuminated from the transparent side or grid side, and the dimensions of the grid may vary from hundreds of microns to centimeters in pitch spacing. The increased charge carrier density at the collection area (electrode overlap) may increase the OPV voltage, increasing its power conversion efficiency.

In some embodiments, an OPV as described herein may have an overall power conversion efficiency of at least 10%, at least 12%, at least 14%, at least 16%, or more. In some embodiments, an OPV including a channel layer as described herein may have an improvement in power conversion efficiency of between 1% and 200% over a comparable device without the disclosed structure. In other embodiments, an OPV including a channel layer as described herein may have an improvement in PCE of between 1% and 100%, between 1% and 50%, between 1% and 20%, or between 1% and 10%.

In certain examples, the channel layer 112 composition includes a fullerene composition, such as disclosed herein. The fullerene composition may comprise any fullerene known to a person of skill in the art. Exemplary fullerenes include, but are not limited to, C₆₀, C₇₀, C₆₀-SAM, PC₆₁BM, WS—C₆₀, C₆₀-ETA, PCBA, C₆₀(OH)₂₄₋₂₆, PCBB-2CN-2C8, ICMA, and combinations thereof. In some examples, the channel layer 112 composition is a neat fullerene composition. For example, the neat fullerene composition may be C₆₀ or C₇₀. In one embodiment, the channel layer composition is a mixed fullerene composition. In one embodiment, the mixed fullerene composition comprises two or more fullerene compounds. In one embodiment, the mixed fullerene composition comprises a fullerene compound mixed with a non-fullerene compound.

The channel layer 112 may have a thickness in a range of 0.1-100 nm, 1-100 nm, 50-100 nm, 1-50 nm, 10-50 nm or 25-75 nm. In one embodiment, the channel layer has a thickness of between about 1 nm and about 15 nm.

### Substrate

As noted above, the OPV device 100 may include a substrate 114 positioned to support the OPV cell. In certain examples, such as depicted in FIG. 1A, the substrate 114 may be positioned adjacent to the first electrode 102. Alternatively, an intermediate layer (such as an anti-reflective coating layer) may be positioned between the electrode 102 and the substrate 114.

The substrate may be any material configured to support the OPV cell. In certain examples, the substrate 114 is a transparent material such as glass. In alternative examples, the substrate 114 may be a semi-transparent or opaque material.

### OPV or OPD With 3D Organic Framework

In another aspect, an organic photovoltaic (OPV) or an organic photodetector (OPD) device is provided that includes an anode; a cathode; and an active layer, disposed between the anode and the cathode, where the active layer comprises a first 3-dimensional (3D) organic framework according to any embodiment described herein.

In some embodiments, the active layer comprises a second 3D organic framework with a different composition than the first 3D organic framework. The second 3D organic framework can include a plurality of nodes, A2; a plurality of linkers, B2; and a plurality of interstitial void spaces, C2, where each node is attached to at least one other node A2 by a linker B2, and the plurality of interstitial void spaces C2 can contain one or more molecules, E2.

In some embodiments, the second 3D organic framework comprises a second plurality of nodes A2, a second plurality of linkers B2, and the plurality of interstitial void spaces C2, that can include one or more molecules E2.

In some embodiments, the second 3D organic framework does not include at least one of an acceptor or a donor.

In some embodiments, the second 3D organic framework does not include either an acceptor or a donor.

In some embodiments, at least one of A2, B2, or E2 is a second electron donor; and at least one of A2, B2, or E2 is a second electron acceptor. In some embodiments, the second 3D organic framework can have a structure of any of the 3D organic frameworks described herein (e.g., those including nodes, A, linkers, B, and molecules, E.)

In some embodiments, the OPV or OPD device further comprises at least one layer selected from the group consisting of hole transporting layer, an electrode transporting layer, an anode buffer, and a cathode buffer.

In some embodiments, the OPV or OPD device further comprises a hole transporting layer.

In some embodiments, the OPV or OPD device further comprises an electrode transporting layer.

In some embodiments, the OPV or OPD device further comprises an anode buffer.

In some embodiments, the OPV or OPD device further comprises a cathode buffer.

In some embodiments, the OPV or OPD device has a power conversion efficiency of at least 12%.

In some embodiments, the OPV or OPD device has a power conversion efficiency of at least 18%.

### OPV Performance Characteristics

In certain examples, the OPV or solar cell may have certain improved performance properties. For example, the solar cells disclosed herein may include an improved power conversion efficiency (PCE). In certain examples, the solar cell may have a PCE of at least 10%, at least 11%, at least 12%, at least 13%, at least 14%, or at least 15%. In some examples, the multi-junction solar cells disclosed herein have PCEs in a range of 10-15%, 12-15%, or 14-15%.

The solar cells disclosed herein may have a high open circuit voltage (V_{oc}). The V_{oc} may be at least 1 V, at least 1.1 V, at least 1.2 V, at least 1.3 V, at least 1.4 V, at least 1.5 V, in a range of 1.5-2 V, in a range of 1.3-1.7 V, or in a range of 1.5-1.6 V.

The solar cells disclosed herein may have an improved fill factor (FF). The FF may be at least 50%, at least 60%, at least 65%, at least 70%, at least 75%, at least 80%, in a range of 50-80%, in a range of 60-80%, in a range of 65-75%, or approximately 70%.

The solar cells disclosed herein may have a high short circuit current (J_{sc}). The J_{sc} may be in a range of 10-30 mA/cm², 10-15 mA/cm², or 12-13 mA/cm².

The solar cells disclosed herein may have an improved external quantum efficiency (EQE). The EQE may at least 50%, at least 60%, at least 65%, at least 70%, at least 75%, at least 80%, at least 85%, in a range of 65-85%, in a range of 65-75%, or approximately 70%, as measured between wavelengths of 500-850 nm and providing a transparency window between wavelengths of less than 600 nm that is filled by the visible-absorbing sub-cell in the tandem structure. The EQE of an OPV or OPD can be further extended into the near infra-red to greater than 1000 nm, or even greater than 1100 nm, or greater than 1200 nm, or even greater than 1300 nm by use of photoactive materials that absorb in the near infra-red.

What is claimed is:

1. A three-dimensional (3D) organic framework, comprising:
a plurality of nodes, A;
a plurality of linkers, B; and
a plurality of interstitial void spaces, C;
wherein each node of the plurality of nodes A is connected to at least another node of the plurality of nodes A through one of the plurality of linkers B;
wherein each of the plurality of interstitial void spaces C can contain one or more molecules E;
wherein at least one of A, B, or E is an electron donor; and
wherein at least one of A, B, or E is an electron acceptor.

2. The 3D organic framework of claim 1, wherein the 3D organic framework is a metal-organic framework.

3. The 3D organic framework of claim 1, wherein the 3D organic framework is a covalent-organic framework.

4. The 3D organic framework of claim 1, wherein the 3D organic framework has a unit cell.

5. The 3D organic framework of claim 4, wherein the 3D organic framework has a cube unit cell of Formula I:

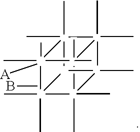

7. The 3D organic framework of claim 4, wherein each B in the unit cell is the same.

8. The 3D organic framework of claim 1, wherein E is not chemically bonded to any A or B.

9. The 3D organic framework of claim 1, wherein A is an acceptor, and B, E, or a different A is a donor.

10. The 3D organic framework of claim 1, wherein B is an acceptor, and A, E, or a different B is a donor.

11. The 3D organic framework of claim 1, wherein E is present and is an acceptor, and A, B, or a different E is a donor.

12. The 3D organic framework of claim 1, wherein the plurality of linkers, B, are organic linkers.

13. The 3D organic framework of claim 1, wherein the one or more molecules, E when present, are organic molecules or organometallic complexes.

14. The 3D organic framework of claim 1, wherein the electron donor has a core structure selected from the group consisting of: 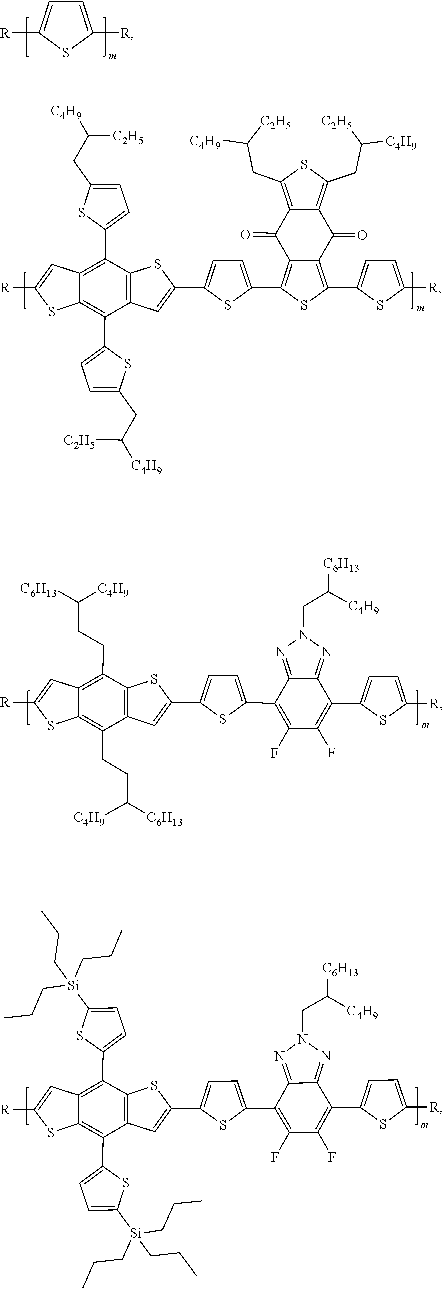 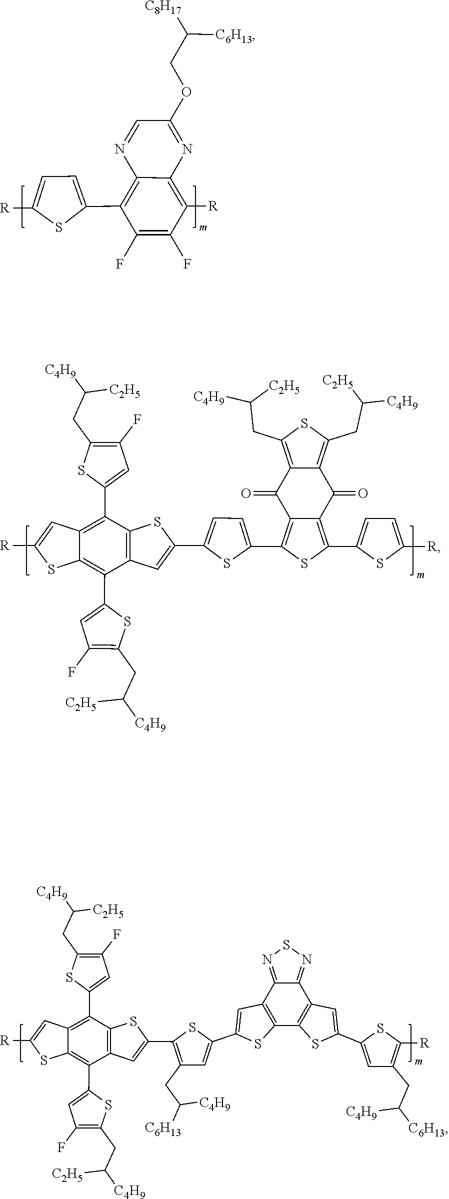 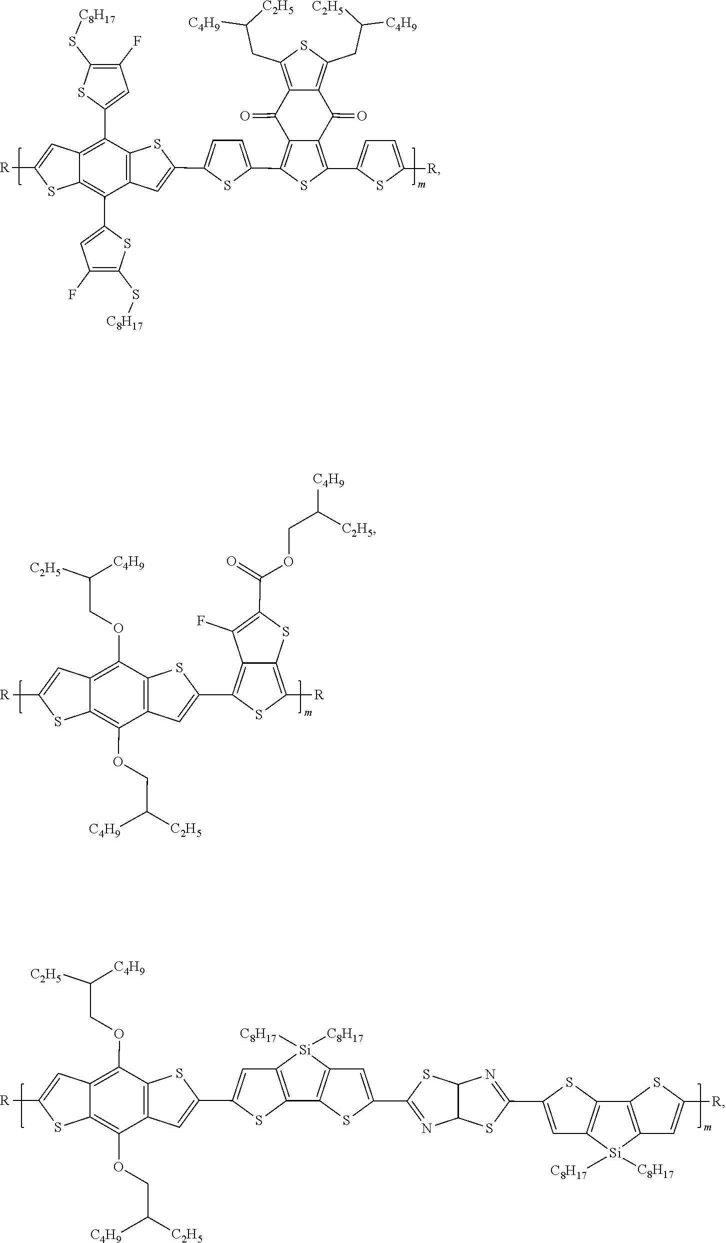 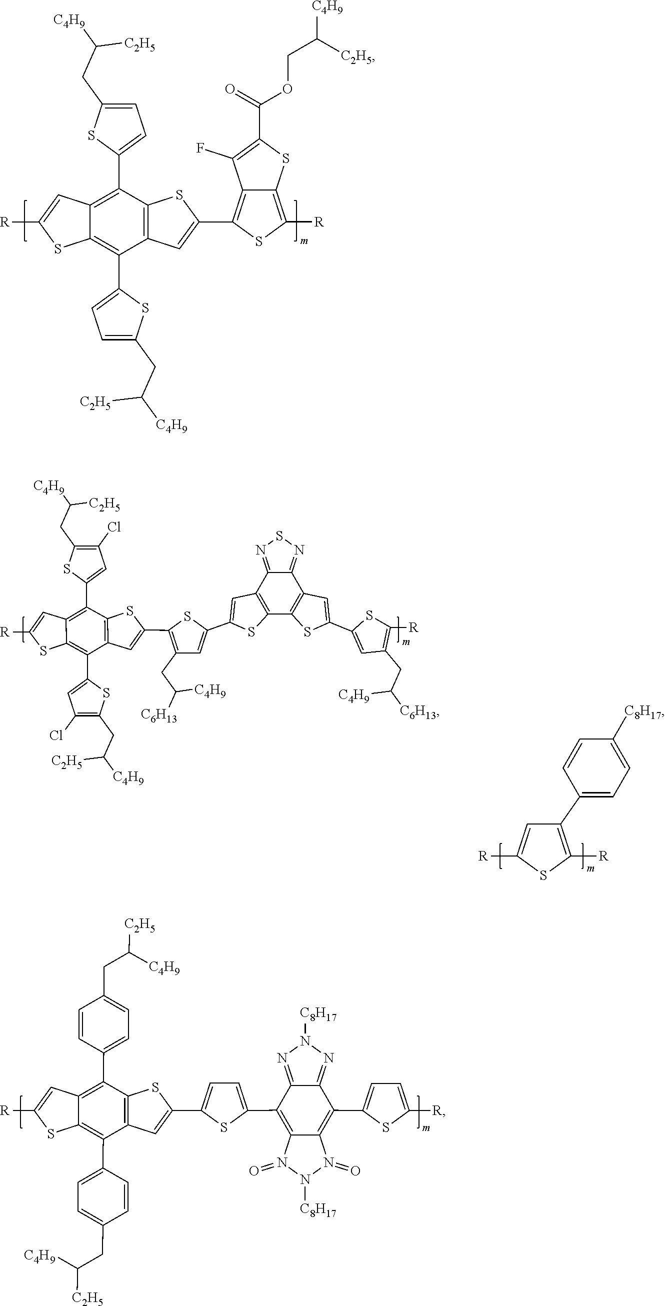 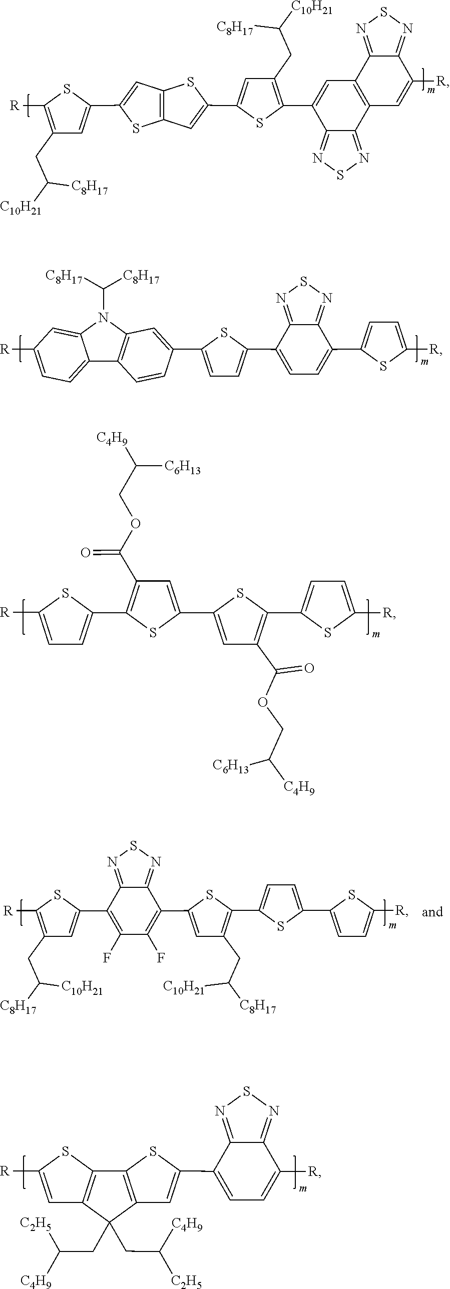
wherein m is an integer from 1 to 5; and
wherein each R is independently selected from the group consisting of

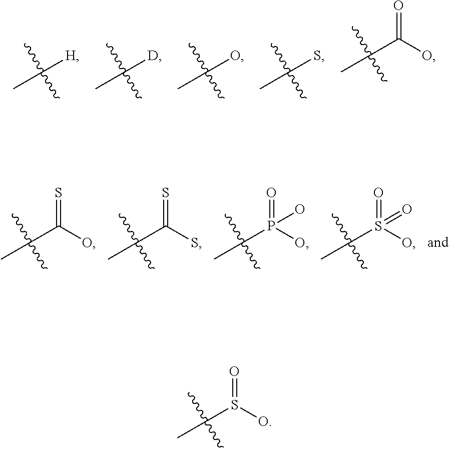

15. The 3D organic framework of claim 1, wherein the electron acceptor has a core structure selected from the group consisting of: 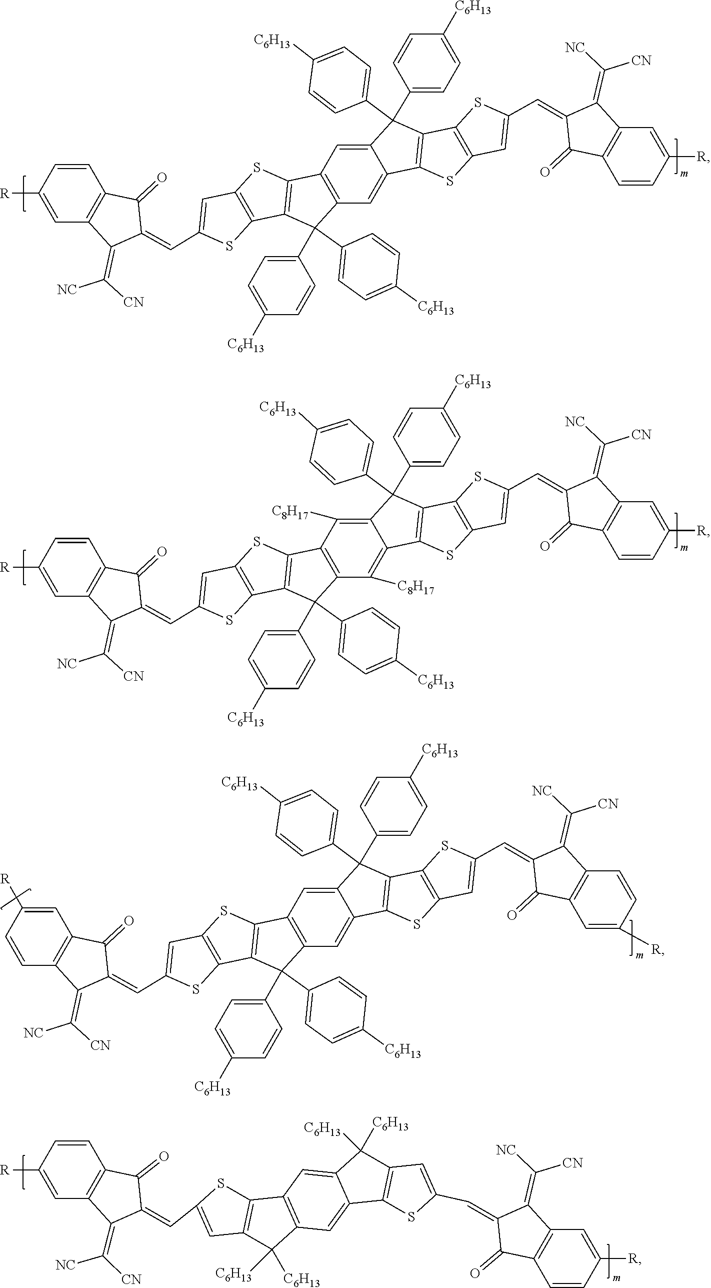 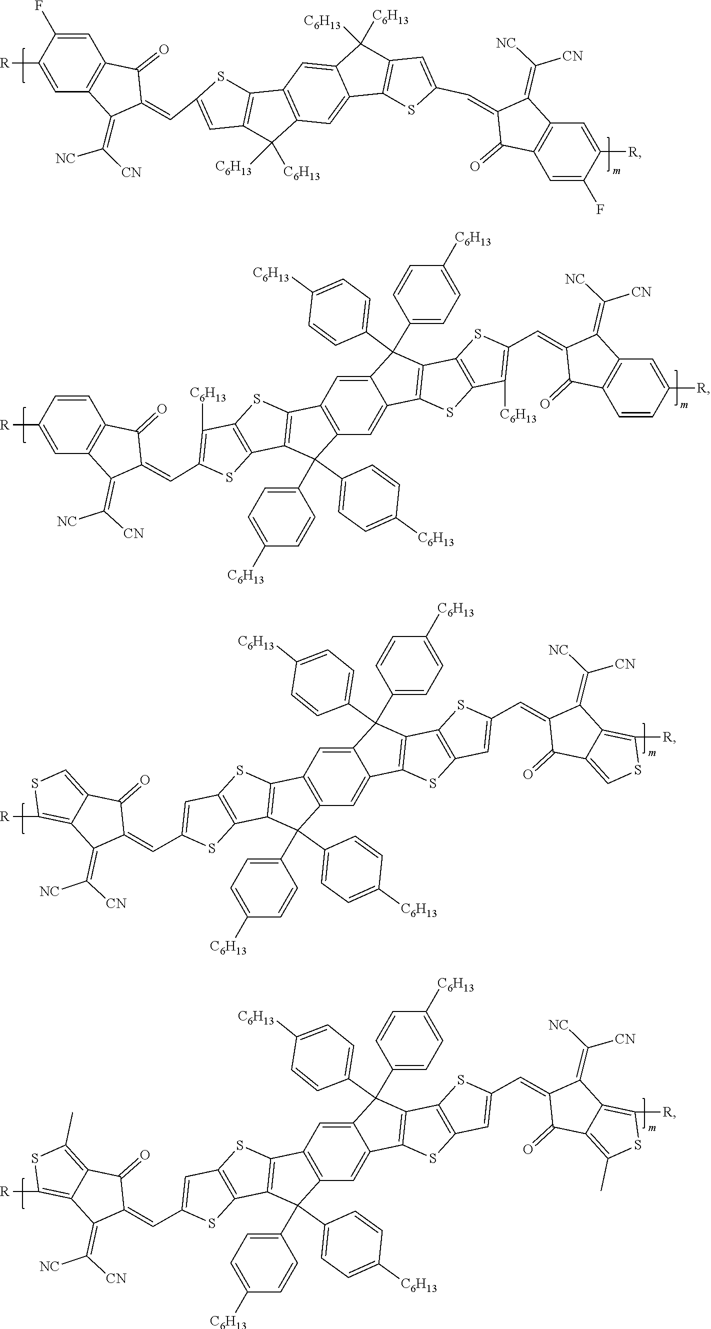 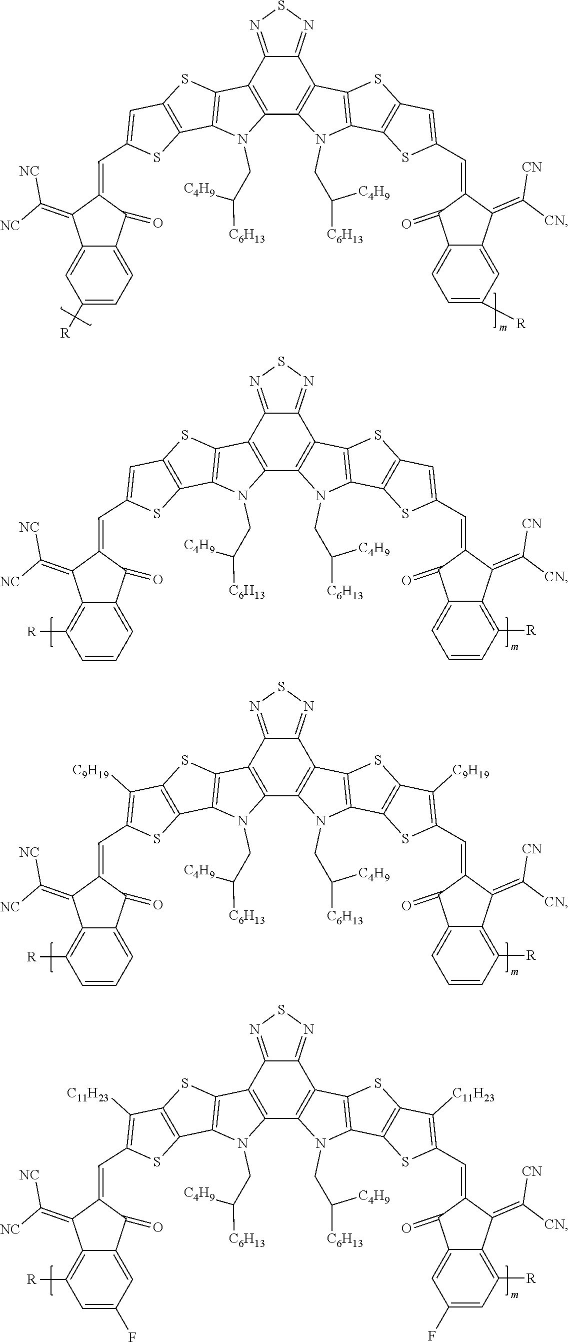 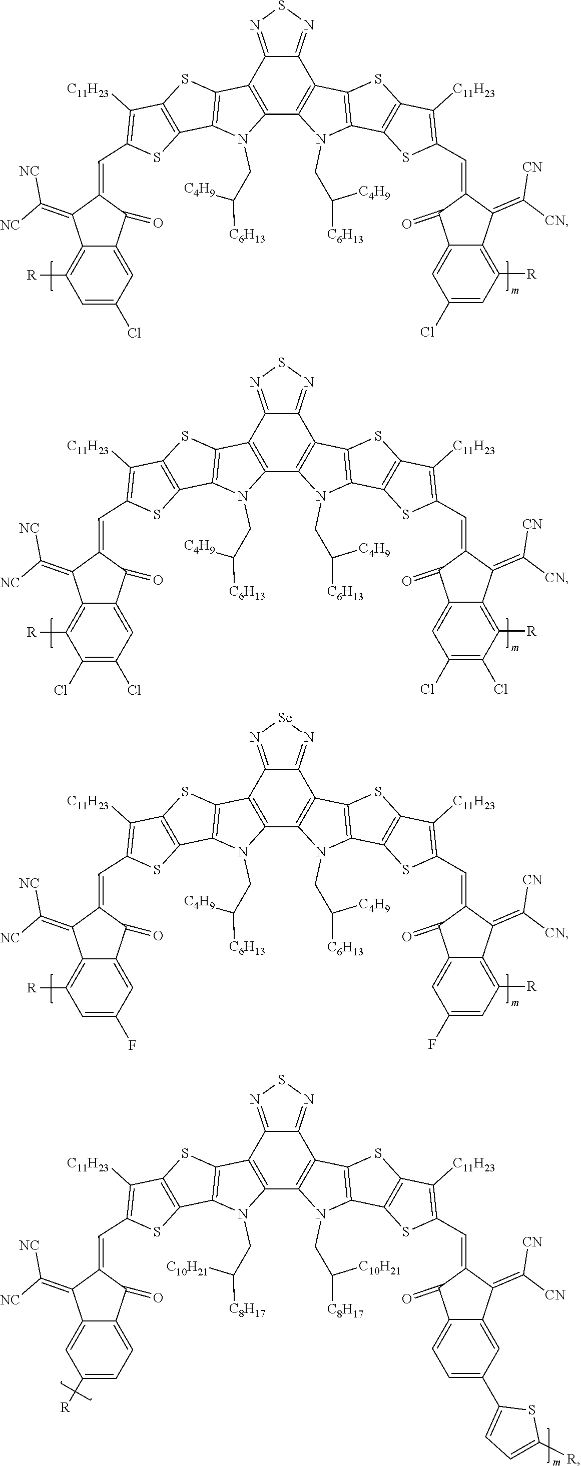 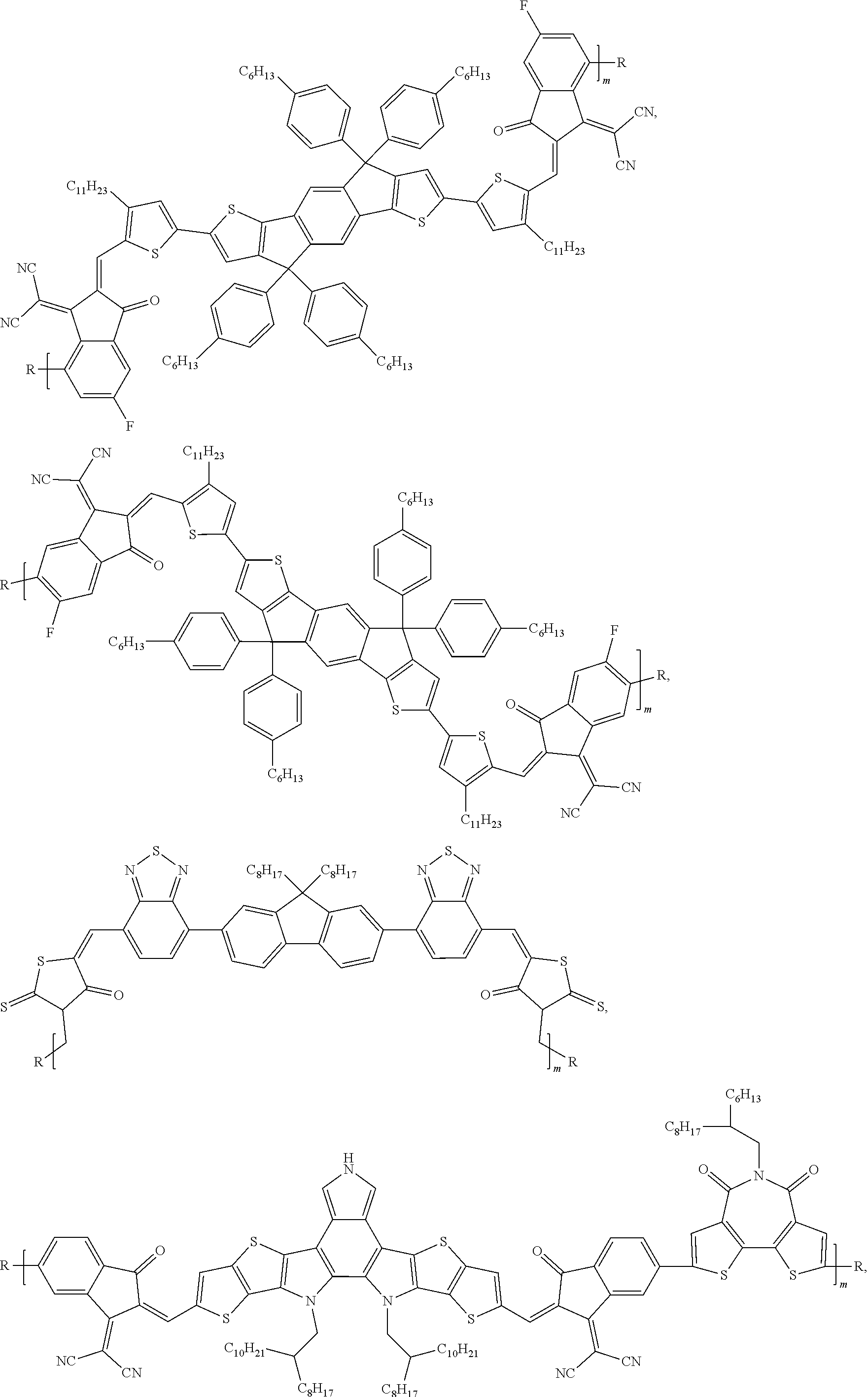 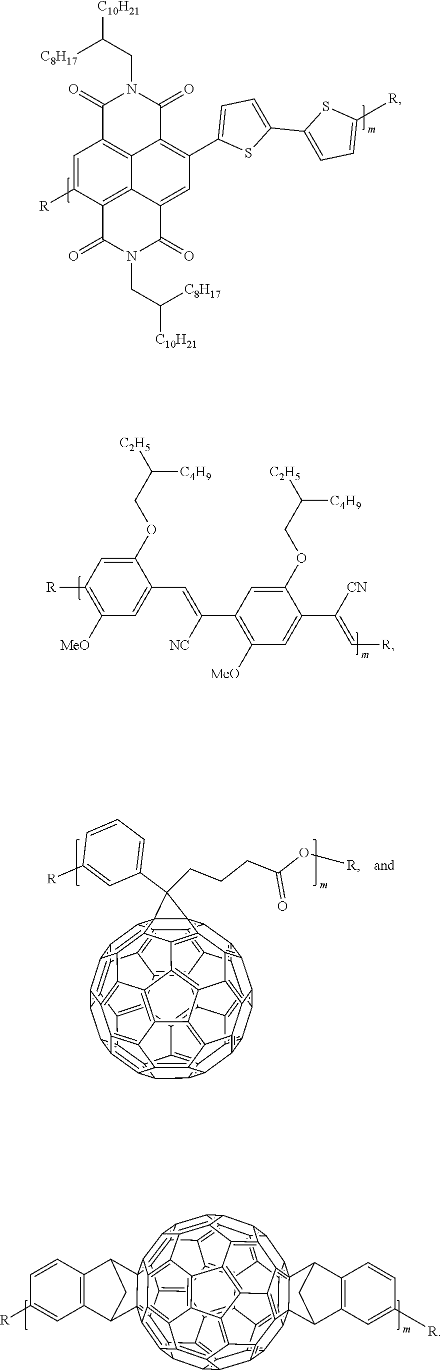
wherein m is an integer from 1 to 5; and
wherein each R is independently selected from the group consisting of

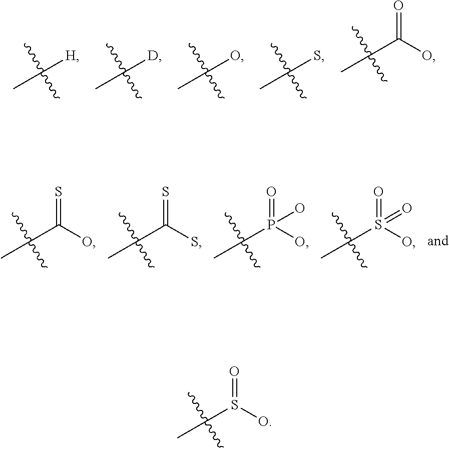

16. An organic photovoltaic (OPV) or an organic photodetector (OPD) device comprising:
an anode;
a cathode; and
an active layer, disposed between the anode and the cathode,
wherein the active layer comprises a first 3-dimensional (3D)) organic framework according to claim 1.

17. The OPV or OPD device of claim 16, wherein the active layer comprises a second 3D) organic framework with a different composition than the first 3D) organic framework, wherein the second 3D organic framework comprises:
a plurality of nodes, A2;
a plurality of linkers, B2; and
a plurality of interstitial void spaces, C2;
wherein each node is attached to at least one other node A2 by a linker B2;
wherein the plurality of interstitial void spaces C2 can contain one or more molecules, E2.

18. The OPV or OPD device of claim 17, wherein the second 3D organic framework comprises a second plurality of nodes A2, a second plurality of linkers B2, and a plurality of interstitial voids C2 that include one or more molecules E2.

19. The OPV or OPD device of claim 17, wherein at least one of A2, B2, or E2 is a second electron donor; and at least one of A2, B2, or E2 is a second electron acceptor.

20. A formulation comprising a 3D organic framework of claim 1.
